(19) United States
(12) Patent Application Publication
(10) Pub. No.: US 2022/0139871 A1
(43) Pub. Date: May 5, 2022

(54) LIGHT-EMITTING ELEMENT INK AND METHOD OF MANUFACTURING DISPLAY DEVICE USING THE LIGHT-EMITTING ELEMENT INK

(71) Applicant: Samsung Display Co., Ltd., Yongin-si (KR)

(72) Inventors: Na Mi HONG, Cheonan-si (KR); Hyo Jin KO, Seoul (KR); Duk Ki KIM, Suwon-si (KR); Jun Bo SIM, Suwon-si (KR); Chang Hee LEE, Seoul (KR); Jae Kook HA, Seoul (KR); Gyu Bong KIM, Suwon-si (KR); Hoi Lim KIM, Seoul (KR)

(21) Appl. No.: 17/451,284

(22) Filed: Oct. 18, 2021

(30) Foreign Application Priority Data
Oct. 30, 2020 (KR) 10-2020-0143101

(51) Int. Cl. H01L 23/00; H01L 25/16; C09D 11/033; C09K 11/62

(52) U.S. Cl. CPC H01L 24/95; H01L 25/167; H01L 33/325; C09K 11/62; C09D 11/033

(57) ABSTRACT

A light-emitting element ink and a method of manufacturing a display device using the light-emitting element ink are provided. The light-emitting element ink comprises a solvent, a dispersant mixed with the solvent, and a plurality of light-emitting elements dispersed in the solvent, each of the light-emitting elements including a plurality of semiconductor layers and an insulating film surrounding parts of outer surfaces of the semiconductor layers, wherein the dispersant includes an aqueous dispersant or an organic dispersant, if the dispersant is the aqueous dispersant, the solvent has a hydrogen bonding parameter, of Hansen's solubility parameters, of less than 7, and if the dispersant is the organic dispersant, the solvent has a hydrogen bonding parameter, of Hansen's solubility parameters, of 7 or greater.

### CROSS-REFERENCE TO RELATED APPLICATION

This application claims priority to and the benefit of Korean Patent Application No. 10-2020-0143101, filed on Oct. 30, 2020, the entire content of which is hereby incorporated by reference.

### BACKGROUND

### 1. Field

Embodiments of the present disclosure relate to light-emitting element ink and a method of manufacturing a display device using the light-emitting element ink.

### 2. Description of the Related Art

Display devices are becoming more important with developments in multimedia technology. Accordingly, various display devices such as an organic light-emitting diode (OLED) display device, a liquid crystal display (LCD) device, and the like have been used.

For example, a display device, which displays an image, includes a display panel such as an OLED display panel or an LCD panel. The display panel, for example, a light-emitting element display panel, may include light-emitting elements. For example, light-emitting diodes (LEDs) may include OLEDs using an organic material as a fluorescent material and inorganic light-emitting diodes (ILEDs) using an inorganic material as a fluorescent material.

### SUMMARY

Embodiments of the present disclosure provide a light-emitting element ink, which includes a dispersant capable of dispersing light-emitting elements and can thus improve the dispersibility of the light-emitting elements.

Embodiments of the present disclosure also provide a method of manufacturing a display device, which can improve the dispersibility of light-emitting elements, after printing, using the light-emitting element ink.

However, embodiments of the present disclosure are not restricted to those set forth herein. The above and other embodiments of the present disclosure will become more apparent to one of ordinary skill in the art to which the present disclosure pertains by referencing the detailed description of the present disclosure given below.

According to an embodiment of the present disclosure, a light-emitting element ink includes a solvent, a dispersant mixed with the solvent, and a plurality of light-emitting elements dispersed in the solvent, each of the light-emitting elements including a plurality of semiconductor layers and an insulating film surrounding parts of outer surfaces of the semiconductor layers, wherein the dispersant includes an aqueous dispersant or an organic dispersant, if the dispersant is the aqueous dispersant, the solvent has a hydrogen bonding parameter, of Hansen's solubility parameters, of less than 7, and if the dispersant is the organic dispersant, the solvent has a hydrogen bonding parameter, of Hansen's solubility parameters, of 7 or greater.

In one embodiment, the solvent includes a copolymer compound including heads, which are bonded to the light-emitting elements, and tails, which are coupled to the heads, and the copolymer compound includes a polymer self-assembly monolayer (P-SAM).

In one embodiment, the heads include at least one selected from among phosphonic acid, carboxylic acid, trimethoxysilane, and amine.

In one embodiment, the tails include at least one selected from among polyalkylene oxide, polyurethane, polyacrylate, alkyl, amine, fatty acid, and polyester.

In one embodiment, the dispersant has a molecular weight of 1,000 to 100,000 Mw (Daltons).

In one embodiment, if the dispersant is the aqueous dispersant, the solvent has a hydrogen bonding parameter, of Hansen's solubility parameters, of 7 to 15.

In one embodiment, if the dispersant is the organic dispersant, the solvent has a hydrogen bonding parameter, of Hansen's solubility parameters, of 5 or more and less than 7.

In one embodiment, the light-emitting elements are included in an amount of 0.01% to 10% by weight based on 100% by weight of the light-emitting element ink.

In one embodiment, the dispersant is included in an amount of 10% to 100% by weight based on 100% by weight of the light-emitting elements.

In one embodiment, the semiconductor layers include a first semiconductor layer and a second semiconductor layer and a light-emitting layer, which is between the first semiconductor layer and the second semiconductor layers, and the insulating film surrounds an outer surface of at least the light-emitting layer.

In one embodiment, the dispersant is chemically bonded to the insulating film.

According to an embodiment of the present disclosure, the method of manufacturing a display device, includes preparing a light-emitting element ink, which includes a solvent, a dispersant, and a plurality of light-emitting elements, and a target substrate, on which a first electrode and a second electrode are formed, spraying the light-emitting element ink onto the target substrate, and settling the light-emitting elements on the first electrode and the second electrode by forming an electric field on the target substrate, wherein the dispersant includes an aqueous dispersant or an organic dispersant, if the dispersant is the aqueous dispersant, the solvent has a hydrogen bonding parameter, of Hansen's solubility parameters, of less than 7, and if the dispersant is the organic dispersant, the solvent has a hydrogen bonding parameter, of Hansen's solubility parameters, of 7 or greater.

In one embodiment, the solvent includes a copolymer compound including heads, which are bonded to the light-emitting elements, and tails, which are coupled to the heads, and the copolymer compound includes a polymer self-assembly monolayer (P-SAM).

In one embodiment, the heads include at least one selected from among phosphonic acid, carboxylic acid, trimethoxysilane, and amine.

In one embodiment, the tails include at least one selected from among polyalkylene oxide, polyurethane, polyacrylate, alkyl, amine, fatty acid, and polyester.

In one embodiment, the dispersant has a molecular weight of 1,000 to 100,000 Mw (Daltons).

In one embodiment, if the dispersant is the aqueous dispersant, the solvent has a hydrogen bonding parameter, of Hansen's solubility parameters, of 7 to 15.

In one embodiment, if the dispersant is the organic dispersant, the solvent has a hydrogen bonding parameter, of Hansen's solubility parameters, of 5 or more and less than 7.

In one embodiment, the light-emitting elements are included in an amount of 0.01% to 10% by weight based on 100% by weight of the light-emitting element ink, and the dispersant is included in an amount of 10% to 100% by weight based on 100% by weight of the light-emitting elements.

In one embodiment, the method further includes, after the settling the light-emitting elements, removing the solvent and the dispersant by performing a thermal treatment.

According to the aforementioned and other embodiments of the present disclosure, as a dispersant formed of a copolymer compound including heads and tails is used, the heads can be bonded to light-emitting elements, and the tails can form a chain structure. Therefore, buoyancy and steric hindrance can be generated in a solvent, thereby increasing the dispersibility of the light-emitting elements.

In addition, as a solvent having a set or predetermined range of hydrogen bonding parameters depending on the type or kind of dispersant (for example, whether the dispersant is an aqueous dispersant or an organic dispersant) is used, the dispersibility of the light-emitting elements can be increased. Therefore, clogging of the nozzles of an inkjet printing device with light-emitting element ink including the light-emitting elements can be prevented or reduced.

Moreover, even if the light-emitting element ink including the light-emitting elements drops to each subpixel, the agglomeration of the light-emitting elements can be reduced, the probability of misalignment can be reduced, and the luminance of each subpixel can become uniform (e.g., substantially uniform). Therefore, a uniform (e.g., substantially uniform) number of light-emitting elements can be arranged per unit area of a display device with a high degree of alignment, and the product reliability of the display device can be improved.

Other features and embodiments may be apparent from the following detailed description, the drawings, and the claims.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The above and other embodiments and features of the present disclosure will become more apparent by describing in more detail embodiments thereof with reference to the attached drawings, in which:

FIG. 1 is a plan view of a display device according to an embodiment of the present disclosure;

FIG. 2 is a plan view of a pixel of the display device of FIG. 1;

FIG. 3 is a cross-sectional view taken along lines Q1-Q1′, Q2-Q2′, and Q3-Q3′ of FIG. 2;

FIG. 4 is a perspective view of a light-emitting element according to an embodiment of the present disclosure;

FIG. 5 is a perspective view of a light-emitting element according to another embodiment of the present disclosure;

FIG. 6 is a perspective view of light-emitting element ink according to an embodiment of the present disclosure;

FIG. 7 illustrates a dispersant according to an embodiment of the present disclosure;

FIG. 8 illustrates how the light-emitting element according to the embodiment of FIG. 4 and the dispersant according to the embodiment of FIG. 7 are combined;

FIG. 9 is a perspective view of the light-emitting element ink according to the embodiment of FIG. 6;

FIG. 10 illustrates an inkjet printing device according to an embodiment of the present disclosure;

FIG. 11 is a flowchart illustrating a method of manufacturing a display device according to an embodiment of the present disclosure;

FIGS. 12 through 19 are cross-sectional views illustrating the method of FIG. 11;

FIG. 20 shows images of ink #1 and ink #2 according to Experimental Example 1;

FIG. 21 shows images of ink #1 and ink #2 according to Experimental Example 2;

FIG. 22 is a graph showing the change of the transparency and the back-scattering of ink #3 over time according to Experimental Example 3;

FIG. 23 is a graph showing the change of the transparency and the back-scattering of ink #5 over time according to Experimental Example 3;

FIG. 24 is a graph showing the change of the transparency and the back-scattering of ink #7 over time according to Experimental Example 4; and

FIG. 25 is a graph showing the change of the transparency and the back-scattering of ink #8 over time according to Experimental Example 4.

### DETAILED DESCRIPTION

The subject matter of the present disclosure will now be described more fully hereinafter with reference to the accompanying drawings, in which example embodiments of the disclosure are shown. The subject matter of this disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the spirit and scope of the present disclosure. Similarly, the second element could also be termed the first element.

Each of the features of the various embodiments of the present disclosure may be combined or combined with each other, in part or in whole, and technically various interlocking and driving are possible. Each embodiment may be implemented independently of each other or may be implemented together in an association.

Embodiments of the present disclosure will hereinafter be described with reference to the accompanying drawings.

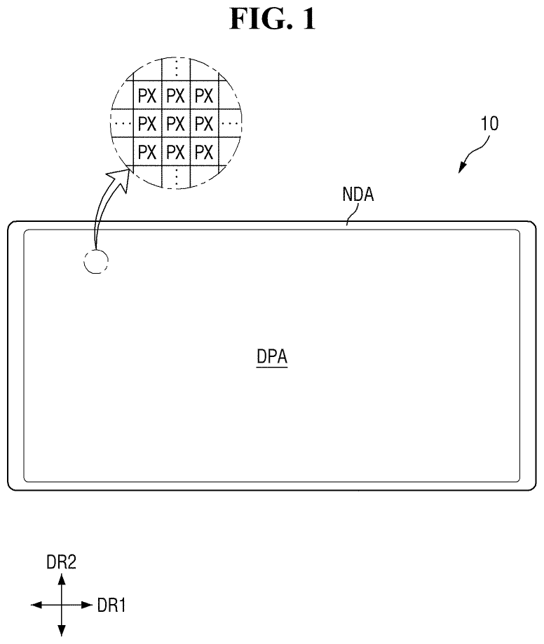

FIG. 1 is a plan view of a display device according to an embodiment of the present disclosure.

Referring to FIG. 1, a display device 10 displays a moving or still image. The display device 10 may refer to nearly all types or kinds of electronic devices that provide a display screen. Examples of the display device 10 may include a television (TV), a notebook computer, a monitor, a billboard, an Internet-of-Things (IoT) device, a mobile phone, a smartphone, a tablet personal computer (PC), an electronic watch, a smartwatch, a watchphone, a head-mounted display, a mobile communication terminal, an electronic notepad, an electronic book, a portable multimedia player (PMP), a navigation device, a gaming console, a digital camera, and a camcorder.

The display device 10 may include a display panel that provides a display screen. Examples of the display panel include an inorganic light-emitting diode (ILED) display panel, an organic LED (OLED) display panel, a quantum-dot light-emitting diode (QLED) display panel, a plasma display panel (PDP), and a field emission display (FED) panel. The display panel of the display device 10 will hereinafter be described as being an ILED display panel, but the present disclosure is not limited thereto.

The shape of the display device 10 may vary. For example, the display device 10 may have a rectangular shape that extends longer in a horizontal direction than in a vertical direction, a rectangular shape that extends longer in the vertical direction than in the horizontal direction, a square shape, a rectangular shape having rounded corners, another polygonal shape, or a circular shape. A display area DPA of the display device 10 may have a similar shape to the display device 10. FIG. 1 illustrates that the display device 10 and the display area DPA have a rectangular shape that extends longer in the horizontal direction than in the vertical direction.

The display device 10 may include the display area DPA and a non-display area NDA. The display area DPA is an area in which a screen is displayed, and the non-display area NDA is an area in which a screen is not displayed. The display area DPA may also be referred to as an active area, and the non-display area NDA may also be referred to as an inactive area. The display area DPA may generally account for a middle portion or a central portion of the display device 10.

The display area DPA may include a plurality of pixels PX. The pixels PX may be arranged in row and column directions. The pixels PX may have a rectangular or square shape in a plan view, but the present disclosure is not limited thereto. In one or more embodiments, the pixels PX may have a rhombus shape that is inclined with respect to a set or particular direction. The pixels PX may be alternately arranged in a stripe fashion or a PENTILE® arrangement structure (e.g., an RGBG matrix, RGBG structure, or RGBG matrix structure). PENTILE® is a duly registered trademark of Samsung Display Co., Ltd. Each of the pixels PX may include one or more light-emitting elements 30 that emit light of a set or predetermined wavelength range to emit light of a set or predetermined color.

The non-display area NDA may be on the periphery of the display area DPA. The non-display area NDA may surround the entire display area DPA or a portion of the display area DPA. The display area DPA may have a rectangular shape, and the non-display area NDA may be adjacent to four sides of the display area DPA. The non-display area NDA may form the bezel of the display device 10. Wires or circuit drivers included in the display device 10 may be in the non-display area NDA, or external devices may be mounted in the non-display area NDA.

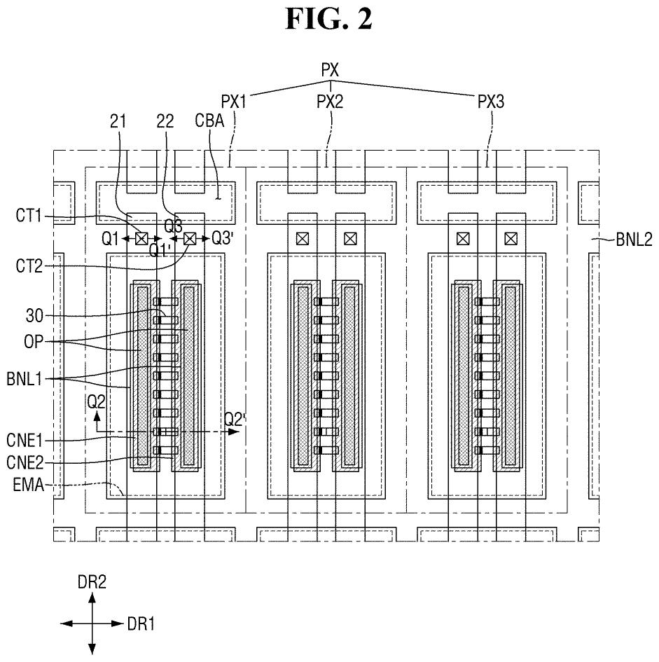

FIG. 2 is a plan view of a pixel of the display device of FIG. 1.

Referring to FIG. 2, a pixel PX may include a plurality of subpixels PXn (where n is an integer of 1 to 3). For example, the pixel PX may include first, second, and third subpixels PX1, PX2, and PX3. The first subpixel PX1 may emit light of a first color, the second subpixel PX2 may emit light of a second color, and the third subpixel PX3 may emit light of a third color. The first, second, and third colors may be blue, green, and red, respectively, but the present disclosure is not limited thereto. In one or more embodiments, the subpixels PXn may emit light of the same color. FIG. 2 illustrates that the pixel PX includes three subpixels PXn, but the present disclosure is not limited thereto. For example, the pixel PX may include more than three subpixels PXn.

Each of the subpixels PXn may include an emission area EMA and a non-emission area. The emission area EMA may be an area in which one or more light-emitting elements 30 emit light of a set or particular wavelength range, and the non-emission area may be an area that light emitted from the light-emitting elements 30 does not arrive at and no light is thus emitted from (e.g., the non-emission area may be an area that is not designed to emit light). The emission area EMA may include an area in which the light-emitting elements 30 are included, and an area that outputs light emitted from the light-emitting elements 30.

However, the present disclosure is not limited to this. The emission area EMA may further include an area in which light emitted from the light-emitting elements 30 is reflected or refracted by another element. A plurality of light-emitting elements 30 may be in the subpixels PXn, and a plurality of emission areas EMA, including areas where the plurality of light-emitting elements 30 are included and areas adjacent to the areas where the plurality of light-emitting elements 30 are included, may be formed.

Each of the subpixels PXn may include a cut area CBA, which is in the non-emission area. The cut area CBA may be on one side, in a second direction DR2, of the emission area EMA. The cut area CBA may be between emission areas EMA of a pair of adjacent subpixels PXn in the second direction DR2. For example, in the display area DPA of the display device 10, a plurality of emission areas EMA and a plurality of cut areas CBA may be arranged. For example, the plurality of emission areas EMA or the plurality of cut areas CBA may be arranged one after another in a first direction DR1, and the plurality of emission areas EMA or the plurality of cut areas CBA may be alternately arranged in the second direction DR2. The distance, in the first direction DR1, between the plurality of cut areas CBA may be smaller than the distance, in the first direction DR1, between the plurality of emission areas EMA. A second bank BNL2 may be between the plurality of cut areas CBA and the plurality of emission areas EMA, and the distance between the plurality of cut areas CBA and the plurality of emission areas EMA may vary depending on the width of the second bank BNL2. No light-emitting elements 30 are in the cut area CBA of each of the subpixels PXn so that no light is emitted from the cut area CBA of each of the subpixels PXn (e.g., cut area CBA may be designed not to emit light), but parts of electrodes (21 and 22) may be in the cut area CBA of each of the subpixels PXn to be separate from each other. The electrodes (21 and 22) may be cut and divided in the cut area CBA of each of the subpixels PXn.

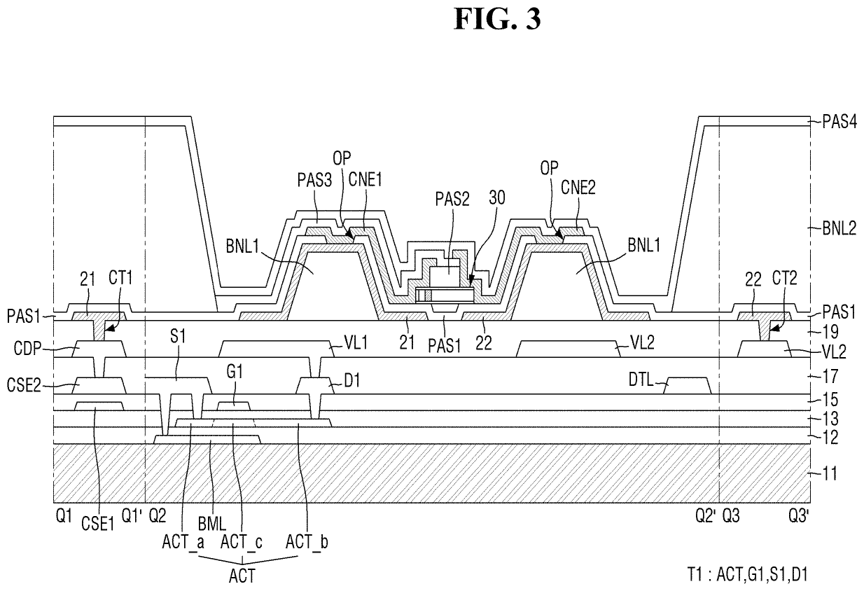

FIG. 3 is a cross-sectional view taken along lines Q1-Q1′, Q2-Q2′, and Q3-Q3′ of FIG. 2. FIG. 3 illustrates a cross-sectional view taken from one end portion to the other portion of one of the light-emitting elements 30 in the first subpixel PX1 of FIG. 2.

Referring to FIG. 3 and further to FIG. 2, the display device 10 may include a first substrate 11 and a semiconductor layer, a plurality of conductive layers, and a plurality of insulating layers, which are on the first substrate 11. The semiconductor layer, the conductive layers, and the insulating layers may form a circuit layer and a light-emitting element layer of the display device 10.

The first substrate 11 may be an insulating substrate. The first substrate 11 may be formed of an insulating material such as glass, quartz, and/or a polymer resin. Also, the first substrate 11 may be a rigid substrate, or may be a flexible substrate that is bendable, foldable, and/or rollable.

A light-blocking layer BML may be on the first substrate 11. The light-blocking layer BML may overlap with an active layer ACT of a first transistor T1. The light-blocking layer BML may include a material capable of blocking or reducing transmission of light, and thus, incidence of light upon the active layer ACT of the first transistor T1 may be prevented or reduced. For example, the light-blocking layer BML may be formed of an opaque metal capable of blocking or reducing the transmission of light, but the present disclosure is not limited thereto. In some embodiments, the light-blocking layer BML may not be provided.

A buffer layer 12 may be not only on the light-blocking layer BML, but also on the entire surface of the first substrate 11. The buffer layer 12 may be formed on the first substrate 11 to protect the first transistor T1 from moisture that may penetrate the first substrate 11, which is susceptible to moisture, and may perform a surface planarization function. The buffer 12 may include (or consist of) a plurality of inorganic layers that are alternately stacked. For example, the buffer layer 12 may be formed as a multilayer layer in which inorganic layers including at least one selected from silicon oxide (SiOₓ), silicon nitride (SiNₓ), and silicon oxynitride (SiOₓN_{y}) are alternately stacked.

The semiconductor layer may be on the buffer layer 12. The semiconductor layer may include the active layer ACT of the first transistor T1. The semiconductor layer may partially overlap with a gate electrode G1 in a first gate conductive layer.

FIG. 3 illustrates only the first transistor T1 of the first subpixel PX1, but the number of transistors included in the first subpixel PX1 is not particularly limited. The first subpixel PX1 may include more than one transistor. For example, the first subpixel PX1 may include more than one transistor including the first transistor T1, for example, two or three transistors.

The semiconductor layer may include polycrystalline silicon, monocrystalline silicon, and/or an oxide semiconductor. In a case where the semiconductor layer includes an oxide semiconductor, the active layer ACT may include a plurality of conductor regions (ACT_a and ACT_b) and a channel region ACT_c between the conductor regions (ACT_a and ACT_b). The oxide semiconductor may be an oxide semiconductor including indium (In). For example, the oxide semiconductor may be indium tin oxide (ITO), indium zinc oxide (IZO), indium gallium oxide (IGO), indium zinc tin oxide (IZTO), indium gallium tin oxide (IGTO), indium gallium zinc oxide (IGZO), and/or indium gallium zinc tin oxide (IGZTO), but the present disclosure is not limited thereto.

In one or more embodiments, the semiconductor layer may include polycrystalline, which is formed by crystallizing amorphous silicon. In this case, the conductor regions of the active layer ACT may be regions doped with impurities.

A first gate insulating layer 13 is on the semiconductor layer and the buffer layer 12. The first gate insulating layer 13 may be not only on the semiconductor layer, but also on the entire surface of the buffer layer 12. The first gate insulating layer 13 may function as the gate insulating layer of each of the transistors of the first subpixel PX1. The first gate insulating layer 13 may be formed of an inorganic material such as, for example, SiOₓ, SiNₓ, and/or SiOₓN_{y}, as an inorganic layer or a stack of such inorganic layers.

The first gate conductive layer may be on the first gate insulating layer 13. The first gate conductive layer may include the gate electrode G1 of the first transistor T1 and a first capacitor electrode CSE1 of a storage capacitor. The gate electrode G1 may overlap with the channel region of the active layer ACT in a thickness direction. The first capacitor electrode CSE1 may overlap with a second capacitor electrode CSE2 in the thickness direction. The first capacitor electrode CSE1 may be coupled to, and integrally formed with, the gate electrode G1. The first capacitor electrode CSE1 may overlap with the second capacitor electrode CSE2 in the thickness direction so that the storage capacitor may be formed between the first capacitor electrode CSE1 and the second capacitor electrode CSE2.

The first gate conductive layer may be formed as a single layer or a multilayer layer including at least one selected from molybdenum (Mo), aluminum (Al), chromium (Cr), gold (Au), titanium (Ti), nickel (Ni), neodymium (Nd), copper (Cu), and an alloy thereof, but the present disclosure is not limited thereto.

A first interlayer insulating layer 15 may be on the first gate conductive layer. The first interlayer insulating layer 15 may perform the functions of an insulating layer between the first gate conductive layer and other layers thereon. A first interlayer insulating layer 15 may cover and protect the first gate conductive layer. The first interlayer insulating layer 15 may be formed of an inorganic material such as, for example, SiOₓ, SiNₓ, and/or SiOₓN_{y}, as an inorganic layer or a stack of such inorganic layers.

A first data conductive layer is on the first interlayer insulating layer 15. The first data conductive layer may include a first source electrode S1, a second drain electrode D1, a data line DTL, and the second capacitor electrode CSE2.

The first source electrode S1 and the first drain electrode D1 of the first transistor T1 may be in contact (e.g., physical contact) with the conductor regions (ACT_a and ACT_b) of the active layer ACT via contact holes that penetrate the first interlayer insulating layer 15 and the first gate insulating layer 13. The first source electrode S1 of the first transistor T1 may be electrically coupled to the light-blocking layer BML via another contact hole.

The data line DTL may transmit a data signal to the other transistors of the first subpixel PX1. In one or more embodiments, the data line DTL may be coupled to source/drain electrodes of the other transistors of the first subpixel PX1 and may thus transmit a signal applied thereto to the source/drain electrodes of the other transistors of the first subpixel PX1.

The second capacitor electrode CSE2 may overlap with the first capacitor electrode CSE1 in the thickness direction. For example, the second capacitor electrode CSE2 may be integrally formed with, and coupled to, the first source electrode S1.

The first data conductive layer may be formed as a single layer or a multilayer layer including at least one selected from Mo, Al, Cr, Au, Ti, Ni, Nd, Cu, and an alloy thereof, but the present disclosure is not limited thereto.

The second interlayer insulating layer 17 may be on the first data conductive layer. The second interlayer insulating layer 17 may function as an insulating layer between the first data conductive layer and layers on the first data conductive layer. Also, the second interlayer insulating layer 17 may cover and protect the first data conductive layer. The second interlayer insulating layer 17 may be formed of an inorganic material such as, for example, SiOₓ, SiNₓ, and/or SiOₓN_{y}, as an inorganic layer or a stack of such inorganic layers.

A second data conductive layer may be on the second interlayer insulating layer 17. The second data conductive layer may include a first voltage line VL1, a second voltage line VL2, and a first conductive pattern CDP. A high-potential voltage (or a first power supply voltage) provided to the first transistor T1 may be applied to the first voltage line VL1, and a low-potential voltage (or the second power supply voltage) provided to a second electrode 22 may be applied to the second voltage line VL2. Alignment signals for aligning the light-emitting elements 30 may be applied to the second voltage line VL2 during the fabrication of the display device 10.

The first conductive pattern CDP may be coupled to the second capacitor electrode CSE2 through a contact hole that is formed in the second interlayer insulating layer 17. The second capacitor electrode CSE2 may be integrally formed with the first source electrode S1, and the first conductive pattern CDP may be electrically coupled to the first source electrode S1. The first conductive pattern CDP may be in contact (e.g., physical contact) with a first electrode 21, and the first transistor T1 may transmit the first power supply voltage applied thereto from the first voltage line VL1 to the first electrode 21 via the first conductive pattern CDP. FIG. 3 illustrates that the second data conductive layer includes one first voltage line VL1 and one second voltage line VL2, but the present disclosure is not limited thereto. The second data conductive layer may include more than one first voltage line VL1 and more than one second voltage line VL2.

The second data conductive layer may be formed as a single- or multilayer layer including at least one selected from Mo, Al, Cr, Au, Ti, Ni, Nd, Cu, and an alloy thereof, but the present disclosure is not limited thereto.

A first planarization layer 19 may be on the second data conductive layer. The first planarization layer 19 may include an organic insulating material such as polyimide (PI) and may perform a surface planarization function.

A plurality of first banks BNL1, the electrodes (21 and 22), the light-emitting elements 30, a plurality of contact electrodes (CNE1 and CNE2), and the second bank BNL2 may be on the first planarization layer as elements of a display element layer. Also, a plurality of insulating layers (PAS1, PAS2, PAS3, and PAS4) may be on the first planarization layer 19.

The first banks BNL1 may be directly on the first planarization layer 19. The first banks BNL1 may extend in the second direction DR2 within the first subpixel PX1 and may be within the emission area EMA, instead of extending into neighboring subpixels PXn of the first subpixel PX1 in the second direction DR2. The first banks BNL1 may be spaced apart from each other in the first direction DR1, and the light-emitting elements 30 may be between the first banks BNL1. A plurality of first banks BNL1 may be provided in each of the subpixels PXn to form linear patterns. FIG. 3 illustrates that there are provided two first banks BNL1 in each of the subpixels PXn, but the number of first banks BNL1 is not particularly limited. In one or more embodiments, more than two first banks BNL1 may be provided depending on the number of electrodes (21 and 22).

The first banks BNL1 may protrude, at least in part, from the top surface of the first planarization layer 19. Parts of the first banks BNL1 that protrude may have inclined sides surfaces, and light emitted from the light-emitting elements 30 may be reflected by the electrodes (21 and 22) on the first banks BNL1 to be emitted in an upward direction from the first planarization layer 19. The first banks BNL1 may not only provide an area in which to arrange the light-emitting elements 30, but also function as a reflecting barrier capable of reflecting light emitted from the light-emitting elements 30 in the upward direction from the first planarization layer 19. The sides of the first banks BNL1 may be linearly inclined, but the present disclosure is not limited thereto. In one or more embodiments, the first banks BNL1 may have a semi-circular or elliptical shape having a curved outer surface. The first banks BNL1 may include an organic insulating material such as polyimide, but the present disclosure is not limited thereto.

The electrodes (21 and 22) may be on the first banks BNL1 and the first planarization layer 19. The electrodes (21 and 22) may include the first and second electrodes 21 and 22. The first and second electrodes 21 and 22 may extend in the second direction DR2 and may be spaced apart from each other in the first direction R1.

The first and second electrodes 21 and 22 may extend in the second direction R2 in the first subpixel PX1 and may be cut and divided in the cut area CBA. For example, the cut area CBA of the first subpixel PX1 may be between the emission area EMA of the first subpixel PX1 and an emission area EMA of a neighboring subpixel PXn adjacent to the first subpixel PX1 in the second direction DR2, and the first and second electrodes 21 and 22 may be cut and divided in the cut area CBA, but the present disclosure is not limited thereto. In one or more embodiments, some of the electrodes (21 and 22) may extend beyond the first subpixel PX1, without being cut and divided in the cut area CBA, or only one selected from the first and second electrodes 21 and 22 may be cut and divided in the cut area CBA.

The first electrode 21 may be electrically coupled to the first transistor T1 via a first contact hole CT1, and the second electrode 22 may be electrically coupled to the second voltage line VL2 via a second contact hole CT2. For example, the first electrode 21 may be in contact (e.g., physical contact) with the first conductive pattern CDP through the first contact hole CT1, which penetrates the first planarization layer 19 in a portion of the second bank BNL2 that extends in the first direction DR1, and the second electrode 22 may be in contact (e.g., physical contact) with the second voltage line VL2 through the second contact hole CT2, which penetrates the first planarization layer 19 in the portion of the second bank BNL2 that extends in the first direction DR1. However, the present disclosure is not limited to this example. In another example, the first and second contact holes CT1 and CT2 may be in the emission area EMA, which is surrounded by the second bank BNL2, and not overlap with the second bank BNL2.

FIGS. 2 and 3 illustrate that one first electrode 21 and one second electrode 22 are in each of the subpixels PXn, but the present disclosure is not limited thereto. In one more embodiments, more than one first electrode 21 and more than one second electrode 22 may be provided in each of the subpixels PXn. The first and second electrodes 21 and 22 may not necessarily extend in only one direction, and the shape of the first and second electrodes 21 and 22 may vary. For example, the first and second electrodes 21 and 22 may be curved and/or bent in part, or one selected from the first and second electrodes 21 and 22 may surround the other electrode.

The first and second electrodes 21 and 22 may be directly on the first banks BNL1. The first and second electrodes 21 and 22 may be formed to have a greater width than the first banks BNL1. For example, the first and second electrodes 21 and 22 may cover the outer surfaces of the first banks BNL1. The first and second electrodes 21 and 22 may be on side surfaces of the first banks BNL1, and the distance between the first and second electrodes 21 and 22 may be smaller than the distance between the first banks BNL1. The first and second electrodes 21 and 22 may be included, at least in part, directly on the first planarization layer 19 and may thus fall on the same plane. However, the present disclosure is not limited thereto. In one or more embodiments, the electrodes (21 and 22) may have a smaller width than the first banks BNL1. The electrodes (21 and 22) may cover at least one side surface of each of the first banks BNL1 and thus to reflect light emitted from the light-emitting elements 30.

The electrodes (21 and 22) may include a conductive material (e.g., an electrically conductive material) having high reflectance. For example, the electrodes (21 and 22) may include a metal having high reflectance such as silver (Ag), Cu, and/or Al and/or may include an alloy of Al, Ni, and/or lanthanum (La). The electrodes (21 and 22) may reflect light, emitted from the light-emitting elements 30 to travel toward the sides of the first banks BNL1, in an upward direction from the first subpixel PX1.

However, the present disclosure is not limited to this, and the electrodes (21 and 22) may further include a transparent conductive material. For example, the electrodes (21 and 22) may include a material such as ITO, IZO, and/or indium tin zinc oxide (ITZO). In some embodiments, each of the electrodes (21 and 22) may form a structure in which a transparent conductive material and a metal having high reflectance are stacked into more than one layer, or may be formed as a single layer including a transparent conductive material and a metal having high reflectance. For example, each of the electrodes (21 and 22) may have a stack of ITO/Ag/ITO, ITO, ITO/Ag/IZO, and/or ITO/Ag/ITZO/IZO.

The electrodes (21 and 22) may be electrically coupled to the light-emitting elements 30, and set or predetermined voltages may be applied to the electrodes (21 and 22) so that the light-emitting elements 30 may emit light. The electrodes (21 and 22) may be electrically coupled to the light-emitting elements 30 via the contact electrodes (CNE1 and CNE2) and may transmit electrical signals applied thereto to the light-emitting elements 30 via the contact electrodes (CNE1 and CNE2).

One selected from the first and second electrodes 21 and 22 may be electrically coupled to the anode electrodes of the light-emitting elements 30, and the other electrode may be electrically coupled to the cathode electrodes of the light-emitting elements 30. However, the present disclosure is not limited to this. In one or more embodiments, one selected from the first and second electrodes 21 and 22 may be electrically coupled to the cathode electrodes of the light-emitting elements 30, and the other electrode may be electrically coupled to the anode electrodes of the light-emitting elements 30.

The electrodes (21 and 22) may be used to form an electric field in the first subpixel PX1 to align the light-emitting elements 30. The light-emitting elements 30 may be arranged between the first and second electrodes 21 and 22 by an electric field formed on the first and second electrodes 21 and 22. The light-emitting elements 30 may be sprayed onto the electrodes (21 and 22) via inkjet printing. When ink including the light-emitting elements 30 is sprayed on the electrodes (21 and 22), an electric field may be formed by applying alignment signals to the electrodes (21 and 22). The light-emitting elements 30 dispersed in the ink may receive a dielectrophoretic force from the electric field, and as the alignment direction and the location of the light-emitting elements 30 change, the light-emitting elements 30 may be aligned on the electrodes (21 and 22).

A first insulating layer PAS1 may be on the first planarization layer 19. The first insulating layer PAS1 may cover the first banks BNL1 and the first and second electrodes 21 and 22. The first insulating layer PAS1 may protect the first and second electrodes 21 and 22 and may insulate (e.g., electrically insulate) the first and second electrodes 21 and 22 from each other. The first insulating layer PAS1 may prevent or reduce direct contact of the light-emitting elements 30, which are on the first insulating layer PAS1, with other elements, and thus, may prevent or reduce damage to the light-emitting elements 30 by other elements.

For example, the first insulating layer PAS1 may include openings OP, which expose parts of the first and second electrodes 21 and 22. The openings OP may expose parts of the electrodes (21 and 22) that are on the top surfaces of the first banks BNL1. Parts of the contact electrodes (CNE1 and CNE2) may be in contact (e.g., physical contact) with the exposed parts of the electrodes (21 and 22) through the openings OP.

The first insulating layer PAS1 may be formed to have a top surface recessed, in part, between the first and second electrodes 21 and 22. For example, as the first insulating layer PAS1 covers the first and second electrodes 21 and 22, the top surface of the first insulating layer PAS1 may be stepped between the first and second electrodes 21 and 22, conforming to the shape of the electrodes (21 and 22) therebelow. However, the present disclosure is not limited to this.

The second bank BNL2 may be on the first insulating layer PAS1. In a plan view, the second bank BNL2 may include parts that extend in the first direction DR1 and parts that extend in the second direction DR2 and may thus be arranged in a lattice pattern. The second bank BNL2 may be included along the boundaries of each of the subpixels PXn to define each of the subpixels PXn.

Also, the second bank BNL2 may surround the emission area EMA and the cut area CBA of each of the subpixels PXn to separate the emission area EMA and the cut area CBA of each of the subpixels PXn. The first and second electrodes 21 and 22 may extend in the second direction DR2 across parts of the second bank BNL2 that extend in the first direction DR1. Parts of the second bank BNL2 that extend in the second direction DR2 may have a greater width between emission areas EMA than between cut areas CBA. Accordingly, the distance between cut areas CBA may be smaller than the distance between emission areas EMA.

The second bank BNL2 may be formed to have a greater height than the first banks BNL1. The second bank BNL2 may prevent or reduce spilling over of ink between different subpixels PXn during an inkjet printing process performed as part of the fabrication of the display device 10 and may separate ink having the light-emitting elements 30 dispersed therein between different subpixels PXn to prevent or reduce mixture of the ink. The second bank BNL2, like the first banks BNL1, may include polyimide, but the present disclosure is not limited thereto.

The light-emitting elements 30 may be on the first insulating layer PAS1. A plurality of light-emitting elements 30 may be spaced apart from one another in the direction in which the electrodes (21 and 22) extend, e.g., in the second direction DR2, and may be aligned substantially in parallel to one another. The light-emitting elements 30 may extend in one direction, and the direction in which the electrodes (21 and 22) extend may form a substantially right angle with the direction in which the light-emitting elements 30 extend. However, the present disclosure is not limited to this. In one or more embodiments, the light-emitting elements 30 may be arranged not perpendicularly, but diagonally, with respect to the direction in which the electrodes (21 and 22) extend.

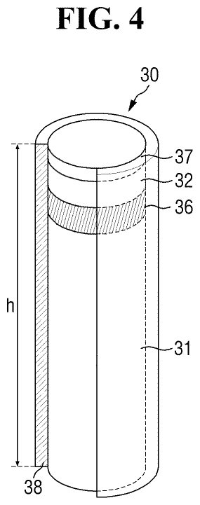

The light-emitting elements 30 may include light-emitting layers 36 (of FIG. 4), and the material of the light-emitting layers 36 of the light-emitting elements 30 may differ from one subpixel PXn to another subpixel PXn of each pixel PX so that different subpixels PXn of each pixel PX may emit light of different wavelength ranges. Accordingly, the first, second, and third subpixels PX1, PX2, and PX3 may emit light of the first, second, and third colors, respectively, but the present disclosure is not limited thereto. In one or more embodiments, different subpixels PXn of each pixel PX may include light-emitting elements of the same type or kind and may thus emit light of substantially the same color.

Both end portions of each of the light-emitting elements 30 may be on the electrodes (21 and 22). The length of the light-emitting elements 30 may be greater than the distance between the first and second electrodes 21 and 22, and both end portions of each of the light-emitting elements 30 may be on the first and second electrodes 21 and 22. For example, first end portions of the light-emitting elements 30 may be on the first electrode 21, and second end portions of the light-emitting elements 30 may be on the second electrode 22.

In each of the light-emitting elements 30, a plurality of layers may be arranged in a direction perpendicular (e.g., substantially perpendicular) to the top surface of the first substrate 11 or the top surface of the first planarization layer 19. The direction in which the light-emitting elements 30 extend may be parallel (e.g., substantially parallel) to the top surface of the first planarization layer 19, and a plurality of semiconductor layers included in each of the light-emitting elements 30 may be sequentially arranged in a direction parallel (e.g., substantially parallel) to the top surface of the first planarization layer 19. However, the present disclosure is not limited to this. In one or more embodiments, the plurality of semiconductor layers may be arranged in the direction perpendicular (e.g., substantially perpendicular) to the top surface of the first planarization layer 19.

Both end portions of each of the light-emitting elements 30 may be in contact (e.g., physical contact) with the contact electrodes (CNE1 and CNE2). For example, an insulating film 38 (of FIG. 4) may not be formed at one end of each of the light-emitting elements 30 so that parts of semiconductor layers 31 and 32 (of FIG. 4) and/or an electrode layer 37 (of FIG. 4) of each of the light-emitting elements 30 may be exposed and may be in contact (e.g., physical contact) with the contact electrodes (CNE1 and CNE2), but the present disclosure is not limited thereto. In one or more embodiments, at least a portion of the insulating film 38 may be removed so that the sides of the semiconductor layers 31 and 32 may be partially exposed. The exposed sides of the semiconductor layers 31 and 32 of each of the light-emitting elements 30 may be in direct contact (e.g., physical contact) with the contact electrodes (CNE1 and CNE2).

A second insulating layer PAS2 may be in part on the light-emitting elements 30. For example, the width of the second insulating layer PAS2 may be smaller than the length of the light-emitting elements 30, and the second insulating layer PAS2 may be on the light-emitting elements 30 to surround the light-emitting elements 30 and expose both end portions of each of the light-emitting elements. The second insulating layer PAS2 may initially cover the light-emitting elements 30, the electrodes (21 and 22), and the first insulating layer PAS1 during the fabrication of the display device 10 and may then be removed to expose both end portions of each of the light-emitting elements 30. The second insulating layer PAS2 may extend in the second direction DR2 over the first insulating layer PAS1 and thus to form a linear or island pattern in the first subpixel PX1 in a plan view. The second insulating layer PAS2 may protect the light-emitting elements 30 and may fix the light-emitting elements 30 during the fabrication of the display device 10.

The contact electrodes (CNE1 and CNE2) and a third insulating layer PAS3 may be on the second insulating layer PAS2.

The contact electrodes (CNE1 and CNE2) may extend in one direction and may be on the electrodes 21 and 22. The contact electrodes (CNE1 and CNE2) may include a first contact electrode CNE1, which is on the first electrode 21, and a second contact electrode CNE2, which is on the second electrode 22. The contact electrodes (CNE1 and CNE2) may be spaced apart from, and face, each other. For example, the first and second contact electrodes CNE1 and CNE2 may be on the first and second electrodes 21 and 22, respectively, to be spaced apart from each other in the first direction DR1. The contact electrodes (CNE1 and CNE2) may form stripe patterns in the emission area EMA of the first subpixel PX1.

The contact electrodes (CNE1 and CNE2) may be in contact (e.g., physical contact) with the light-emitting elements 30. The first contact electrode CNE1 may be in contact (e.g., physical contact) with the first end portions of the light-emitting elements 30, and the second contact electrode CNE2 may be in contact (e.g., physical contact) with the second end portions of the light-emitting elements 30. The semiconductor layers of each of the light-emitting elements 30 may be exposed at both ends of the corresponding light-emitting element 30, and the contact electrodes (CNE1 and CNE2) may be in contact (e.g., physical contact) with, and electrically coupled to, the semiconductor layers of each of the light-emitting elements 30. Sides of the contact electrodes (CNE1 and CNE2) that are in contact (e.g., physical contact) with both end portions of each of the light-emitting elements 30 may be on the second insulating layer PAS2. The first contact electrode CNE1 may be in contact (e.g., physical contact) with the first electrode 21 through an opening OP that exposes a portion of the top surface of the first electrode 21, and the second contact electrode CNE2 may be in contact with the second electrode 22 through an opening OP that exposes a portion of the top surface of the second electrode 22.

The width of the contact electrodes (CNE1 and CNE2) may be smaller than the width of the electrodes (21 and 22). The contact electrodes (CNE1 and CNE2) may be in contact (e.g., physical contact) with both end portions of each of the light-emitting elements 30 and cover parts of the top surfaces of the first and second electrodes 21 and 22, but the present disclosure is not limited thereto. In one or more embodiments, the contact electrodes (CNE1 and CNE2) may be formed to have a greater width than the electrodes (21 and 22) and thus to cover both sides of each of the electrodes (21 and 22).

The contact electrodes (CNE1 and CNE2) may include a transparent conductive material such as, for example, ITO, IZO, ITZO, and/or Al. Light emitted from the light-emitting elements 30 may travel toward the electrodes (21 and 22) through the contact electrodes (CNE1 and CNE2), but the present disclosure is not limited thereto.

FIGS. 2 and 3 illustrate that two contact electrodes (CNE1 and CNE2) are provided in each of the subpixels PXn, but the present disclosure is not limited thereto. The number of contact electrodes (CNE1 and CNE2) may vary depending on the number of electrodes (21 and 22) in each of the subpixels PXn.

The third insulating layer PAS3 may cover the first contact electrode CNE1. The third insulating layer PAS3 may cover not only the first contact electrode CNE1, but also a side of the second insulating layer PAS2 where the first contact electrode CNE1 is included. For example, the third insulating layer PAS3 may cover the first contact electrode CNE1 and the first insulating layer PAS1 on the first electrode 21. This type or kind of arrangement may be obtained by forming an insulating material layer for forming the third insulating layer PAS3 on the entire surface of the emission area EMA and partially removing the insulating material layer for forming the third insulating layer PAS3 to form the second contact electrode CNE2. In this process, the insulating material layer for forming the third insulating layer PAS3 may be removed together with an insulating material layer for forming the second contact electrode CNE2, and sides of the second and third insulating layers PAS2 and PAS3 may be aligned with each other. A side of the second contact electrode CNE2 may be on the third insulating layer PAS3, and the second contact electrode CNE2 may be insulated (e.g., electrically insulated) from the first contact electrode CNE1 by the third insulating layer PAS3.

A fourth insulating layer PAS4 may be on the entire surface of the display area DPA of the first substrate 11. The fourth insulating layer PAS4 may protect the elements on the first substrate 11 from an external environment. The fourth insulating layer PAS4 may not be provided.

The first, second, third, and fourth insulating layers PAS1, PAS2, PAS3, and PAS4 may include an inorganic insulating material and/or an organic insulating material. For example, the first, second, third, and fourth insulating layers PAS1, PAS2, PAS3, and PAS4 may include an inorganic insulating material such as SiOₓ, SiNₓ, SiOₓN_{y}, aluminum oxide (Al₂O₃), and/or aluminum nitride (AlN), but the present disclosure is not limited thereto. In another example, the first, second, third, and fourth insulating layers PAS1, PAS2, PAS3, and PAS4 may include an organic insulating material such as an acrylic resin, an epoxy resin, a phenolic resin, a polyamide resin, a polyimide resin, an unsaturated polyester resin, a polyphenylene resin, a polyphenylene sulfide resin, benzocyclobutene, a cardo resin, a siloxane resin, a silsesquioxane resin, polymethyl methacrylate, polycarbonate, and/or a polymethyl methacrylate-polycarbonate synthetic resin, but the present disclosure is not limited thereto.

FIG. 4 is a perspective view of a light-emitting element according to an embodiment of the present disclosure.

Referring to FIG. 4, a light-emitting element 30 may be a light-emitting diode (LED), for example, an ILED having a size of several micrometers or nanometers (e.g., a size in a micrometer range or a nanometer range) and formed of an inorganic material. If an electric field is formed in a set or particular direction between two opposite electrodes, the ILED may be aligned between the two electrodes where polarities are formed. The light-emitting element 30 may be aligned by the electric field formed between the two electrodes.

The light-emitting element 30 may have a shape that extends in one direction. The light-emitting element 30 may have the shape of a cylinder, a rod, a wire, and/or a tube, but the shape of the light-emitting element 30 is not particularly limited. In one or more embodiments, the light-emitting element 30 may have the shape of a polygonal column such as a regular cube, a rectangular parallelepiped, and/or a hexagonal column and/or may have a shape that extends in one direction but with a partially inclined outer surface. A plurality of semiconductors included in the light-emitting element 30 may be sequentially included or stacked in the direction in which the light-emitting element 30 extends.

The light-emitting element 30 may include semiconductor layers doped with impurities of an arbitrary conductivity type (e.g., a p-type or an n-type). The semiconductor layers may receive electrical signals from an external power source to emit light of a set or particular wavelength range.

Referring to FIG. 4, the light-emitting element 30 may include a first semiconductor layer 31, a second semiconductor layer 32, a light-emitting layer 36, an electrode layer 37, and an insulating film 38.

The first semiconductor layer 31 may include an n-type semiconductor. In a case where the light-emitting element 30 emits light of a blue wavelength range, the first semiconductor layer 31 may include a semiconductor material AlₓGa_{y}In_{1-x-y}N (where 0≤x≤1, 0≤y≤1, and 0≤x+y≤1). The semiconductor material AlₓGa_{y}In_{1-x-y}N may be at least one selected from AlGaInN, GaN, AlGaN, InGaN, AlN, and InN that are doped with an n-type dopant. The first semiconductor layer 31 may be doped with an n-type dopant, and the n-type dopant may be Si, Ge, or Sn. For example, the first semiconductor layer 31 may be n-GaN doped with n-type Si. The first semiconductor layer 31 may have a length of 1.5 μm to 5 μm, but the present disclosure is not limited thereto.

The second semiconductor layer 32 may be on the light-emitting layer 36. The second semiconductor layer 32 may include a p-type semiconductor. In a case where the light-emitting element 30 emits light of a blue or green wavelength range, the second semiconductor layer 32 may include a semiconductor material AlₓGa_{y}In_{1-x-y}N (where 0≤x≤1, 0≤y≤1, and 0≤x+y≤1). For example, the semiconductor material AlₓGa_{y}In_{1-x-y}N may be at least one selected from AlGaInN, GaN, AlGaN, InGaN, AlN, and InN that are doped with a p-type dopant. The second semiconductor layer 32 may be doped with a p-type dopant, and the p-type dopant may be Mg, Zn, Ca, Se, and/or Ba. For example, the second semiconductor layer 32 may be p-GaN doped with p-type Mg. The second semiconductor layer 32 may have a length of 0.05 μm to 0.10 μm, but the present disclosure is not limited thereto.

FIG. 3 illustrates that the first and second semiconductor layers 31 and 32 are formed as single-layer layers, but the present disclosure is not limited thereto. In one or more embodiments, each of the first and second semiconductor layers 31 and 32 may include more than one layer such as, for example, a clad layer and/or a tensile strain barrier reducing (TSBR) layer, depending on the material of the light-emitting layer 36.

The light-emitting layer 36 may be between the first and second semiconductor layers 31 and 32. The light-emitting layer 36 may include a single layer or a multi-quantum well structure material. In a case where the light-emitting layer 36 includes a material having a multi-quantum well structure, the light-emitting layer 36 may have a structure in which multiple quantum layers and multiple well layers are alternately stacked. The light-emitting layer 36 may emit light by combining electron-hole pairs in accordance with electrical signals applied thereto via the first and second semiconductor layers 31 and 32. In a case where the light-emitting layer 36 emits light of a blue wavelength range, the quantum layers may include a material such as AlGaN and/or AlGaInN. In one or more embodiments, in a case where the light-emitting layer 36 has a multi-quantum well structure in which multiple quantum layers and multiple well layers are alternately stacked, the quantum layers may include a material such as AlGaN and/or AlGaInN, and the well layers may include a material such as GaN and/or AlInN. For example, in a case where the light-emitting layer 36 includes AlGaInN as its quantum layer(s) and AlInN as its well layer(s), the light-emitting layer 36 can emit blue light having a central wavelength range of 450 nm to 495 nm.

However, the present disclosure is not limited to this. In one or more embodiments, the light-emitting layer 36 may have a structure in which a semiconductor material having a large band gap energy and a semiconductor material having a small band gap energy are alternately stacked or may include group III and/or group V semiconductor materials depending on the wavelength of light to be emitted. The type or kind of light emitted by the light-emitting layer 36 is not particularly limited. The light-emitting layer 36 may emit light of a red or green wavelength range as necessary or desired, instead of blue light. The light-emitting layer 36 may have a length of 0.05 μm to 0.10 μm, but the present disclosure is not limited thereto.

Light may be emitted not only from the peripheral surface (e.g., circumferential surface), in a length direction, of the light-emitting element 30, but also from both sides of the light-emitting element 30. The directionality of the light emitted from the light-emitting layer 36 is not particularly limited.

The electrode layer 37 may be an ohmic contact electrode, but the present disclosure is not limited thereto. In one or more embodiments, the electrode layer 37 may be a Schottky contact electrode. The light-emitting element 30 may include at least one electrode layer 37. FIG. 4 illustrates that the light-emitting element 30 includes one electrode layer 37, but the present disclosure is not limited thereto. In one or more embodiments, the light-emitting element 30 may include more than one electrode layer 37, or the electrode layer 37 may not be provided. However, the following description of the light-emitting element 30 may also be directly applicable to a light-emitting element 30 having more than one electrode layer 37 or having a different structure from the light-emitting element 30 of FIG. 4.

The electrode layer 37 may reduce the resistance between the light-emitting element 30 and electrodes (or contact electrodes) when the light-emitting element 30 is electrically coupled to the electrodes (or the contact electrodes). The electrode layer 37 may include a conductive metal (e.g., an electrically conductive material). For example, the electrode layer 37 may include at least one selected from Al, Ti, In, Au, Ag, ITO, IZO, and ITZO. Also, the electrode layer 37 may include a semiconductor material doped with an n-type or p-type dopant. The electrode layer 37 may include the same material or different materials, but the present disclosure is not limited thereto.

The insulating film 38 may surround the first and second semiconductor layers 31 and 32 and the electrode layer 37. For example, the insulating film 38 may surround at least the light-emitting layer 36 and may extend in the direction in which the light-emitting element 30 extends. The insulating film 38 may protect the first semiconductor layer 31, the light-emitting layer 36, the second semiconductor layer 32, and the electrode layer 37. For example, the insulating film 38 may be formed to surround the sides of the first semiconductor layer 31, the light-emitting layer 36, the second semiconductor layer 32, and the electrode layer 37, but to expose both end portions, in the length direction, of the light-emitting element 30.

FIG. 3 illustrates that the insulating film 38 is formed to extend in the length direction of the light-emitting element 30 and to cover the sides of the first semiconductor layer 31, the light-emitting layer 36, the second semiconductor layer 32, and the electrode layer 37, but the present disclosure is not limited thereto. The insulating film 38 may cover the sides of only the light-emitting layer 36 and some of the first and second semiconductor layers 31 and 32 or may cover only a portion of the side of the electrode layer 37 so that the side of the electrode layer 37 may be partially exposed. The insulating film 38 may be formed to be rounded in a cross-sectional view, in a region adjacent to at least one end of the light-emitting element 30.

The insulating film 38 may have a thickness of 10 nm to 1.0 μm, but the present disclosure is not limited thereto. For example, the insulating film 38 may have a thickness of about 40 nm.

The insulating film 38 may include a material with insulating properties such as, for example, SiOₓ, SiNₓ, SiOₓN_{y}, AlN, and/or Al₂O₃. Accordingly, the insulating film 38 can prevent any (or substantially any) short circuit that may occur when the light-emitting layer 36 is placed in direct contact (e.g., physical contact) with electrodes that transmit electrical signals directly to the light-emitting element 30 (or can reduce a likelihood or degree of such a short circuit). Also, because the insulating film 38 includes the light-emitting layer 36 to protect the outer surface of the light-emitting element 30, any (or substantially any) degradation in the emission efficiency of the light-emitting element 30 can be prevented or reduced.

The outer surface of the insulating film 38 may be subjected to surface treatment. The light-emitting element 30 may be sprayed on electrodes in a state of being dispersed in set or predetermined ink. Here, the surface of the insulating film 38 may be hydrophobically or hydrophilically treated to keep the light-emitting element 30 dispersed in the ink without (or substantially without) agglomerating with other neighboring light-emitting elements 30. For example, the insulating film 38 may be surface-treated with a material such as stearic acid and/or 2,3-naphthalene dicarboxylic acid.

A length h of the light-emitting element 30 may be in the range of 1 μm to 10 μm, 2 μm to 6 μm, or, for example, 3 μm to 5 μm. The light-emitting element 30 may have a diameter of 30 nm to 700 nm and may have an aspect ratio of 1.2 to 100, but the present disclosure is not limited thereto. Different light-emitting elements 30 included in the display device 10 may have different diameters depending on the composition of their respective light-emitting layers 36. For example, the light-emitting element 30 may have a diameter of about 500 nm.

The shape and the material of the light-emitting element 30 are not particularly limited. In some embodiments, the light-emitting element 30 may include more layers than those illustrated in FIG. 4 or may have a different shape from that illustrated in FIG. 4.

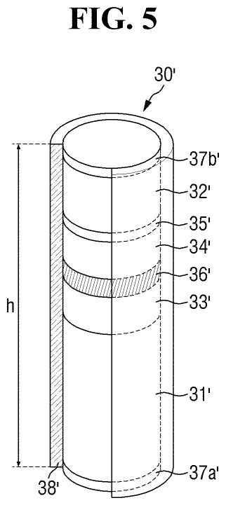

FIG. 5 is a perspective view of a light-emitting element according to another embodiment of the present disclosure.

Referring to FIG. 5, a light-emitting element 30′ may include a first semiconductor layer 31′, a second semiconductor layer 32′, and a light-emitting layer 36′ and may further include a third semiconductor layer 33′, which is between the first semiconductor layer 31′ and the light-emitting layer 36′, and fourth and fifth semiconductor layers 34′ and 35′, which are between the light-emitting layer 36′ and the second semiconductor layer 32′. The light-emitting element 30′ differs from the light-emitting element 30 of FIG. 4 in that it includes a plurality of semiconductor layers (33′, 34′, and 35′) and a plurality of electrode layers (37a′ and 37b′), and that the light-emitting layer 36′ includes a different element or material from the light-emitting layer 36 of FIG. 4. The light-emitting element 30′ will hereinafter be described, focusing mainly on the differences with the light-emitting element 30 of FIG. 4.

The light-emitting layer 36 of the light-emitting element 30 of FIG. 4 may include nitrogen (N) and may thus emit blue or green light. In one or more embodiments, the light-emitting layer 36′ and the semiconductor layers (33′, 34′, and 35′) of the light-emitting element 30′ of FIG. 5 may include a semiconductor that contains at least phosphorus (P). The light-emitting element 30′ may emit red light having a central wavelength range of 620 nm to 750 nm. However, the central wavelength range of the red light is not particularly limited and may be understood as encompassing all wavelength ranges that can be perceived as red light.

In one or more embodiments, the first semiconductor layer 31′ may be an n-type semiconductor layer including a semiconductor material InₓAl_{y}Ga_{1-x-y}P (where 0≤x≤1, 0≤y≤1, and 0≤x+y≤1). The first semiconductor layer 31′ may include at least one selected from InAlGaP, GaP, AlGaP, InGaP, AlP, and InP that are doped with an n-type dopant. For example, the first semiconductor layer 31′ may be n-AlGaInP doped with n-type Si.

The second semiconductor layer 32′ may be a p-type semiconductor layer including a semiconductor material InₓAl_{y}Ga_{1-x-y}P (where 0≤x≤1, 0≤y≤1, and 0≤x+y≤1). The second semiconductor layer 32′ may include at least one selected from InAlGaP, GaP, AlGaNP, InGaP, AlP, and InP that are doped with a p-type dopant. For example, the second semiconductor layer 32′ may be p-GaP doped with p-type magnesium (Mg).

The light-emitting layer 36′ may be between the first and second semiconductor layers 31′ and 32′. The light-emitting layer 36′ may include a single layer or a multi-quantum well structure material and may thus emit light of a set or particular wavelength range. In a case where the light-emitting layer 36′ has a structure in which a quantum layer and a well layer are alternately stacked to form a multi-quantum well structure, the quantum layer may include a material such as AlGaP and/or AlInGaP, and the well layer may include a material such as GaP and/or AlInP. For example, the light-emitting layer 36′ may include AlGaInP as the quantum layer and AlInP as the well layer and may thus emit red light having a central wavelength range of 620 nm to 750 nm.

The light-emitting element 30′ may further include clad layers, which are adjacent to the light-emitting layer 36′. The third and fourth semiconductor layers 33′ and 34′, which are between the first and second semiconductor layers 31′ and 32′, above or below the light-emitting layer 36′, may be clad layers.

The third semiconductor layer 33′ may be between the first semiconductor layer 31′ and the light-emitting layer 36′. The third semiconductor layer 33′, like the first semiconductor layer 31′, may be an n-type semiconductor layer and may include a semiconductor material InₓAl_{y}Ga_{1-x-y}P (where 0≤x≤1, 0≤y≤1, and 0≤x+y≤1). For example, the first semiconductor layer 31′ may include n-AlGaInP, and the third semiconductor layer 33′ may include n-AlInP. However, the present disclosure is not limited to this example.

The fourth semiconductor layer 34′ may be between the light-emitting layer 36′ and the second semiconductor layer 32′. The fourth semiconductor layer 34′ may include a semiconductor material InₓAl_{y}Ga_{1-x-y}P (where 0≤x≤1, 0≤y≤1, and 0≤x+y≤1). For example, the second semiconductor layer 32′ may include p-GaP, and the fourth semiconductor layer 34′ may include p-AlInP.

The fifth semiconductor layer 35′ may be between the second and fourth semiconductor layers 32′ and 34′. The fifth semiconductor layer 35′, like the second and fourth semiconductor layers 32′ and 34′, may be a p-type semiconductor layer. In some embodiments, the fifth semiconductor layer 35′ may reduce the difference in lattice constant between the second and fourth semiconductor layers 32′ and 34′. The fifth semiconductor layer 35′ may be a tensile strain barrier reducing (TSBR) layer. For example, the fifth semiconductor layer 35′ may include p-GaInP, p-AlInP, and/or p-AlGaInP, but the present disclosure is not limited thereto. The third, fourth, and fifth semiconductor layers 33′, 34′, and 35′ may have a length of 0.08 μm to 0.25 μm, but the present disclosure is not limited thereto.

First and second electrode layers 37a′ and 37b′ may be on the first and second semiconductor layers 31′ and 32′. The first electrode layer 37a′ may be on the bottom surface of the first semiconductor layer 31′, and the second electrode layer 37b′ may be on the top surface of the second semiconductor layer 32′. However, the present disclosure is not limited to this, and at least one selected from the first and second electrode layers 37a′ and 37b′ may be omitted. For example, the first electrode layer 37a′ may not be on the bottom surface of the first semiconductor layer 31′, and only the second electrode layer 37b′ may be on the top surface of the second semiconductor layer 32′.

The light-emitting elements 30 may be sprayed onto the electrodes (21 and 22) via inkjet printing. The light-emitting elements 30 may be prepared in an ink state by being dispersed in a solvent and may thus be sprayed onto the electrodes (21 and 22). Then, the light-emitting elements 30 may be arranged between the electrodes (21 and 22) by applying alignment signals to the electrodes (21 and 22). In response to the alignment signals are applied to the electrodes (21 and 22), an electric field may be formed on the electrodes (21 and 22), and the light-emitting elements 30 may receive a dielectrophoretic force from the electric field. Then, as the alignment direction and the location of the light-emitting elements 30 change, the light-emitting elements 30 may be aligned on the electrodes (21 and 22).

In ink including light-emitting elements 30 to be sprayed via inkjet printing, the light-emitting elements 30 may agglomerate in a solvent. In this case, the light-emitting elements 30 may not be properly aligned between the electrodes (21 and 22), thereby causing misalignment. Also, if the light-emitting elements 30 agglomerate and are arranged too densely on one side of each subpixel, the luminance of each subpixel may become nonuniform.

However, because the ink including the light-emitting elements 30 includes a dispersant including a compound with heads and tails, the dispersibility of the light-emitting elements 30 can be improved. In one or more embodiments, the dispersibility of the light-emitting element 30 can be further improved by varying a hydrogen bonding parameter, which is one of the Hansen solubility parameters, depending on the properties of the dispersant, for example, depending on whether the dispersant is an aqueous dispersant or an organic dispersant. Thus, even when the ink including the light-emitting elements 30 is sprayed on each subpixel, aggregation of the light-emitting elements 30 can be reduced. As a result, the probability of misalignment can be reduced, and the luminance of each subpixel can become uniform (e.g., substantially uniform).

The ink including the light-emitting elements 30 will hereinafter be described.

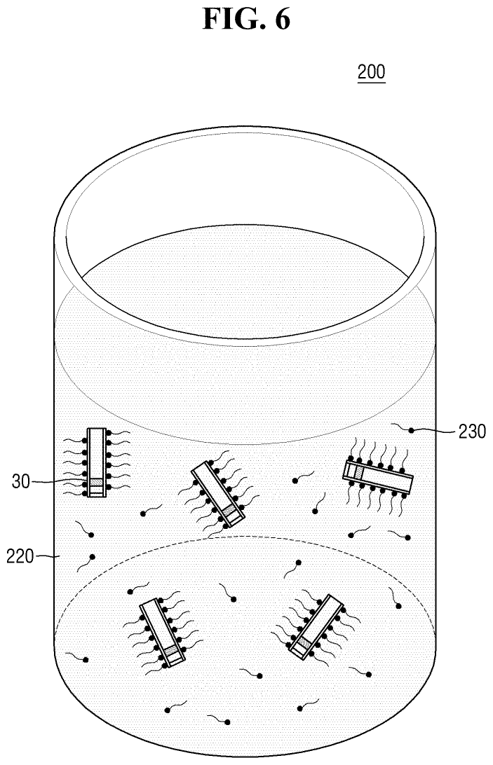

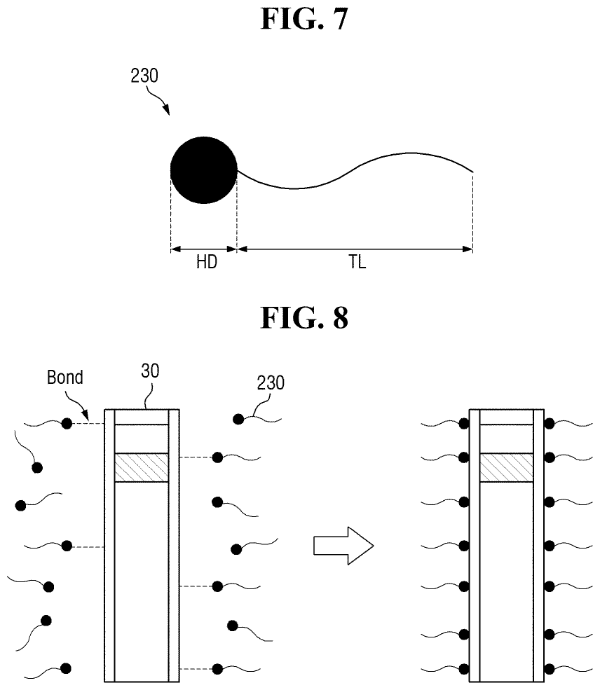

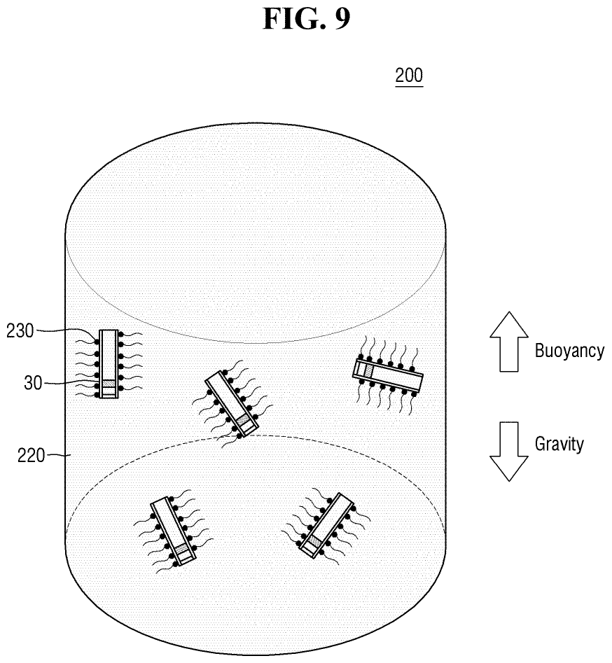

FIG. 6 is a perspective view of light-emitting element ink according to an embodiment of the present disclosure. FIG. 7 illustrates a dispersant according to an embodiment of the present disclosure. FIG. 8 illustrates how the light-emitting element according to the embodiment of FIG. 4 and the dispersant according to the embodiment of FIG. 7 are combined. FIG. 9 is a perspective view of the light-emitting element ink according to the embodiment of FIG. 6.

Referring to FIGS. 6 through 9, light-emitting element ink 200 may include a solvent 220, light-emitting elements 30, and a dispersant 230. Each of the light-emitting elements 30 may be one selected from the light-emitting elements 30 or 30′ of FIGS. 4 and 5, for example, the light-emitting element 30 of FIG. 4 or 5, and thus, a duplicative description thereof will not be repeated. Instead, the solvent 220 primarily will be described hereinafter.

The solvent 220 may be stored with the light-emitting elements 30 dispersed therein and may be an organic solvent that does not react with the light-emitting elements 30 that include semiconductor layers. The solvent 220 may have such a viscosity that it can be discharged through the nozzles of an inkjet printing device in its liquid state. The solvent molecules of the solvent 220 may surround and disperse the light-emitting elements 30. The light-emitting element ink 200 may be prepared as a solution or a colloid including the light-emitting elements 30.

The solvent 220 may include at least one selected from the following: alcohols including methyl alcohol, ethyl alcohol, n-propyl alcohol, isopropyl alcohol, n-butyl alcohol, sec-butyl alcohol, t-butyl alcohol, isobutyl alcohol, and diacetone alcohol; ketones including acetone, methyl ethyl ketone, and methyl isobutyl ketone; glycols including ethylene glycol, diethylene glycol, triethylene glycol, propylene glycol, butylene glycol, hexylene glycol, ethyl phthalyl ethyl glycol (EPEG), 1,3-propanediol, 1,4-butanediol, 1,2,4-butanetriol, 1,5-pentanediol, 1,2-hexanediol, and 1,6-hexanediol; glycol ethers including ethylene glycol monomethyl ether, diethylene glycol monopropyl ether (DGPE), tripropylene glycol n-butyl ether (TGBE), and triethylene glycol monoethyl ether; glycol ether acetates including propylene glycol monomethyl ether acetate (PGMEA); acetates including ethyl acetate, butoxyethoxyethyl acetate, butyl carbitol acetate (BCA), and dihydro terpineol acetate; citrates including triethyl o-acetyl citrate (TAC) and triethyl citrate (TEC); terpineols; trimethylpentanediol monoisobutyrate (TEXANOL); 1-methylpyrrolidone; triamine phosphate (TAP); and glycerin (GL).

The light-emitting element ink 200 may include the dispersant 230 to disperse the light-emitting elements 30 in the solvent 220. The dispersant 230, which is a type or kind of surfactant, may have a structure including (or consisting of) heads HD and tails TL. The heads HD may have affinity to the surfaces of the light-emitting elements 30, which are to be dispersed, and the tails TL may have affinity to the solvent in which the light-emitting elements 30 are to be dispersed, e.g., the solvent 220.

The heads HD of the dispersant 230 include an acid and amine having high reactivity with the insulating films 38 of the light-emitting elements 30 and may thus be able to easily form bonds with the insulating films 38 of the light-emitting elements 30. The heads HD may include, for example, at least one selected from among phosphonic acid, carboxylic acid, trimethoxysilane, and amine.

The heads HD of the dispersant 230 are required to have (or should have) binding stability with the light-emitting elements 30. For example, phosphonic acid has a binding energy ΔE1 of −3.30 eV and a binding energy ΔE2 of −4.41 eV at the initial and last stages, respectively, of a reaction and has a relatively large total binding energy (ΔE1+2) of −7.71 eV, which is the sum of the binding energies ΔE1 and ΔE2. For example, carboxylic acid has a binding energy ΔE1 of −2.73 eV and a binding energy ΔE2 of 1.43 eV at the initial and last stages, respectively, of a reaction and has a relatively large total binding energy (ΔE1+2) of −1.30 eV, which is the sum of the binding energies ΔE1 and ΔE2. For example, amine has a binding energy ΔE1 of −2.34 eV and a binding energy ΔE2 of 1.11 eV at the initial and last stages, respectively, of a reaction and has a relatively large total binding energy (ΔE1+2) of −1.23 eV, which is the sum of the binding energies ΔE1 and ΔE2. For example, trimethoxysilane has a binding energy ΔE1 of −0.91 eV and a binding energy ΔE2 of −1.24 eV at the initial and last stages, respectively, of a reaction and has a relatively large total binding energy (ΔE1+2) of −2.15 eV, which is the sum of the binding energies ΔE1 and ΔE2. Accordingly, the materials of the heads HD can have a large binding energy with respect to the light-emitting elements 30 and can thus have binding stability.

The tails TL of the dispersant 230 are bonded to the heads HD and may have affinity to the solvent 220. The tails TL may have a chain structure and may generate a resistance force, e.g., a drag force, against the light-emitting elements 30 sinking by the force of gravity in the solvent 220. The tails TL may include, for example, at least one selected from among polyalkylene oxide, polyurethane, polyacrylate, alkyl, amine, fatty acid, and polyester.

The dispersant 230 may be formed of a copolymer compound in which the materials of the heads HD and the tails TL are copolymerized. The copolymer compound may include, for example, a polymer self-assembly monolayer (P-SAM).

The dispersant 230, which is bonded to the light-emitting elements 30, may control the degree of sinking of the light-emitting elements 30 by applying a greater buoyancy than the force of gravity in the solvent 220. For example, a sinking force Fₙₑₜ of the light-emitting elements 30 may be obtained by subtracting a buoyancy F_{Buoyancy} and a resistance force F_{Drag} from the force of gravity F_{Gravity}, as indicated by Equation (1):

Fₙₑₜ=F_{Gravity}−(F_{Buoyancy}+F_{Drag}).

Thus, as the heads HD of the dispersant 230 are bonded to the light-emitting elements 30 and the tails TL of the dispersant generate a buoyance and a resistance force in the solvent 220 to reduce the sinking force of the light-emitting elements 30, the dispersibility of the light-emitting elements 30 can be increased.

As already mentioned above, the light-emitting element ink 200 including the dispersant 230 can increase the dispersibility of the light-emitting elements 30. The dispersant 230 may form a chemical bond (or chemical bonds) between the heads HD and the insulating films 38 (see FIG. 4) at the surfaces of the light-emitting elements 30. The tails TL of the dispersant 230 may form a chain structure and may generate steric hindrance, thereby suppressing or reducing the agglomeration of the light-emitting elements 30. Due to the steric hindrance caused by the chain structure of the tails TL of the dispersant, a repulsive force may be formed between the light-emitting elements 30 so that the light-emitting elements 30 may easily be dispersed again. On the contrary, if the dispersant 230 is not provided, an attractive force may be applied between the light-emitting elements 30 so that the light-emitting elements 30 may agglomerate.

The dispersant 230 may be classified into an aqueous dispersant or an organic dispersant. In a case where the dispersant 230 is an aqueous dispersant, the copolymer compound of the dispersant 230 may be aqueous, and in a case where the dispersant 230 is an organic dispersant, the copolymer compound of the dispersant 230 may be organic. The use of the solvent 220 having affinity to the dispersant 230 affects the sinking speed of the light-emitting elements 30, and thus, an appropriate or suitable solvent should be selected. One of the factors of the solvent 220 that affect the dispersant 230 may be a hydrogen bonding parameter, which is one of the Hansen solubility parameters. The Hansen solubility parameters may include three parameters showing solubility properties, e.g., a dispersion parameter, a polarity parameter, and a hydrogen bonding parameter. The hydrogen bonding parameter is characterized by intermolecular interactions caused by hydrogen bonds, and the higher the number of hydrogen bonding sites in each molecule, the higher the value of the hydrogen bonding parameter, of Hansen's solubility parameters.

The light-emitting element ink 200 may be formed to satisfy the range of values of the hydrogen bonding parameter of the solvent 220, depending on the properties of the dispersant 230 (e.g., whether the dispersant 230 is an aqueous dispersant or an organic dispersant) and can thus increase the dispersibility of the light-emitting elements 30.

In a case where the dispersant 230 is an aqueous dispersant, the hydrogen bonding parameter, of Hansen's solubility parameters, of the solvent 220 is 7 or greater. In a case where the dispersant 230 is an organic dispersant, the hydrogen bonding parameter, of Hansen's solubility parameters, of the solvent 220 is 7 or less.

In one or more embodiments, in a case where the dispersant 230 is an aqueous dispersant, a solvent having a hydrogen bonding parameter, of Hansen's solubility parameters, of 7 to 15 may be used as the solvent 220. In this case, when dispersed in the solvent having a hydrogen bonding parameter, of Hansen's solubility parameters, of 7 to 15, the solvent 220 does not cause layer separation or agglomeration of the light-emitting elements 30 and can thus increase the dispersibility of the light-emitting elements 30. Also, in a case where the dispersant 230 is an organic dispersant, a solvent having a hydrogen bonding parameter, of Hansen's solubility parameters, of 5 to 7 may be used as the solvent 220. In this case, when dispersed in the solvent having a hydrogen bonding parameter of 5 to 7, the solvent 220 does not cause layer separation or agglomeration of the light-emitting elements 30 and can thus increase the dispersibility of the light-emitting elements 30.

For example, as an organic dispersant, a copolymer compound including amine and carboxylic acid as heads HD and polyurethane as tails TL and a copolymer compound including amine as heads HD and polyacrylate as tails TL is dispersed properly in a mixed solvent of ethyl phthalyl ethyl glycol (EPEG) and butyl carbitol acetate (BCA) having a hydrogen bonding parameter (dH), of Hansen's solubility parameters, of 5.4.

For example, as an aqueous dispersant, a copolymer compound including amine and phosphonic acid as heads HD and polyacrylate as tails TL is dispersed properly in a mixed solvent of triethyl o-acetyl citrate (TAC) having a hydrogen bonding parameter (dH), of Hansen's solubility parameters, of 7.2, diethylene glycol monopropyl ether (DGPE) having a hydrogen bonding parameter (dH), of Hansen's solubility parameters, of 15, and GL. For example, as an aqueous dispersant, a copolymer compound including amine as heads HD and polyurethane as tails TL is dispersed properly in a triethyl citrate (TEC) solvent having a hydrogen bonding parameter (dH), of Hansen's solubility parameters, of 10.1. For example, as an aqueous dispersant, a copolymer compound including phosphonic acid as heads HD and fatty acid as tails TL is dispersed properly in a DGPE solvent having a hydrogen bonding parameter (dH), of Hansen's solubility parameters, of 11.

Accordingly, as the solvent 220 is formed to satisfy a hydrogen bonding parameter, of Hansen's solubility parameters, of 7 or greater for an aqueous dispersant 230 or a hydrogen bonding parameter, of Hansen's solubility parameters, of 5 to 7 for an organic dispersant 230, the dispersibility of the light-emitting elements 30 can be increased without (or substantially without) causing agglomeration of the light-emitting elements 30 or layer separation in the light-emitting element ink 200.

The dispersant 230 may have a molecular weight of 1,000 Mw (Daltons) to 100,000 Mw (Daltons). The molecular weight of the dispersant 230 may affect the lengths of the heads HD and the tails TL of the dispersant 230. When the molecular weight of the dispersant 230 ranges from 1,000 Mw (Daltons) to 100,000 Mw (Daltons), the lengths of the heads HD and the tails TL of the dispersant 230 increase, and as a result, buoyancy is generated in the solvent 220, thereby increasing the dispersibility of the light-emitting elements 30.

The content (e.g., amount or weight) of the light-emitting elements 30 in the light-emitting element ink 200 may vary depending on the number of light-emitting elements 30 per unit droplet of the light-emitting element ink 200 ejected through a nozzle during printing. For example, the light-emitting elements 30 may be contained in an amount of 0.01% to 10% by weight of the entire light-emitting element ink 200, but the present disclosure is not limited thereto. The content (e.g., amount or weight) of the light-emitting elements 30 may vary depending on the number of light-emitting elements 30 per unit droplet of the light-emitting element ink 200.

The dispersant 230 may be included in the light-emitting element ink 200 in an amount of 10% to 100% by weight of all the light-emitting elements 30. In this case, the dispersibility of the light-emitting elements 300 can be increased. However, the present disclosure is not limited to this. In one or more embodiments, the content (e.g., amount or weight) of the dispersant 230 may vary depending on the number of light-emitting elements 30 per unit droplet of the light-emitting element ink 200.

As the light-emitting element ink 200 includes the solvent 220, which includes the dispersant 230 and satisfies a set or predetermined hydrogen bonding parameter when using an aqueous or organic dispersant, the dispersibility of the light-emitting elements 30 can be improved, and thus, the agglomeration of the light-emitting elements 30 before or during printing can be prevented or reduced. Accordingly, misalignment that may be caused by the agglomeration of the light-emitting elements 30 over electrodes (21 and 22) can be prevented or reduced.

During the fabrication of the display device 10, the light-emitting elements 30 may be arranged on the electrodes (21 and 22) via printing using the light-emitting element ink 200.

An inkjet printing device for spraying the light-emitting element ink 200 will hereinafter be described.

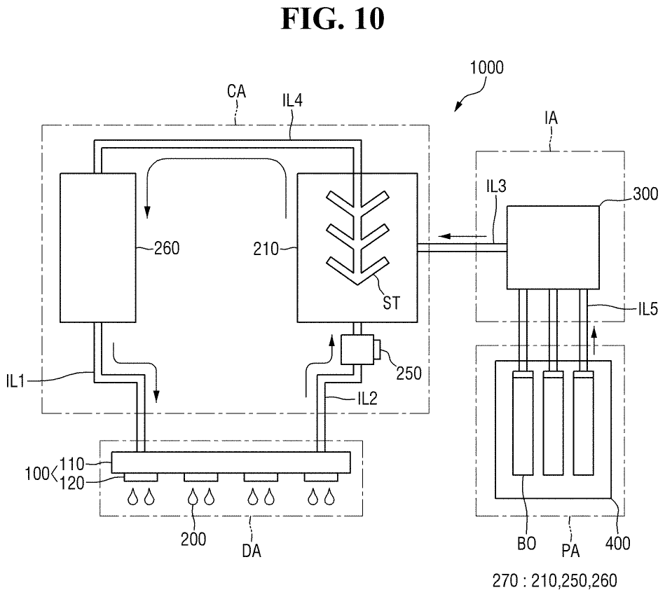

FIG. 10 illustrates an inkjet printing device according to an embodiment of the present disclosure.

Referring to FIG. 10, an inkjet printing device 1000 may include a spray area DA, a circulation area CA, an injection area IR, and a preparation area PA.

The spray area DA may be an area in which light-emitting element ink 200 is to be sprayed. A printhead unit 100 may be in the spray area DA. The printhead unit 100 may spray light-emitting element ink 200 including a plurality of light-emitting elements through the nozzles of an inkjet head 120.

The circulation area CA may be an area in which the light-emitting element ink 200, which is provided to the printhead unit 100, is circulated. In the circulation area CA, the light-emitting element ink 200 including light-emitting elements 30 is circulated so that any (or substantially any) discrepancy in the number of light-emitting elements 30 included in each unit droplet of the light-emitting element ink 200 can be minimized or reduced.

The circulation area CA may include an ink circulation unit 270. The ink circulation unit 270 provides the light-emitting element ink 200 to, or receives the light-emitting element ink 200 from, the printhead unit 100 to circulate the light-emitting element ink 200.

The ink circulation unit 270 may be coupled to the printhead unit 100 through first and second connecting pipes IL1 and IL2. In one or more embodiments, the ink circulation unit 270 may supply the light-emitting element ink 200 to the printhead unit 100 through the first connecting pipe IL1 and may receive the light-emitting element ink 200 from the printhead unit 100 through the second connecting pipe IL2.

The ink circulation unit 270 may include a first ink storage unit 260, a second ink storage unit 210, and a pressure pump 250. The first ink storage unit 260 may be coupled to the printhead unit 100 through the first connecting pipe IL1, the first and second ink storage units 260 and 210 may be coupled to each other through a fourth connecting pipe IL4, the second ink storage unit 210 may be coupled to the printhead unit 100 through the second connecting pipe IL2, and the pressure pump 250 may be between the second ink storage unit 210 and the printhead unit 100. In this manner, a single ink circulation system may be formed.

The first ink storage unit 260 may temporarily store or accommodate the light-emitting element ink 200 before supplying the light-emitting element ink 200 to the printhead unit 100, and may deliver the light-emitting element ink 200 to the printhead unit 100. The first ink storage unit 260 may deliver the light-emitting element ink 200 provided thereto from the second ink storage unit 210 through the fourth connecting pipe IL4, to the printhead unit 100 through the first connecting pipe IL1.

The second ink storage unit 210 may store and/or accommodate the light-emitting element ink 200 before supplying the light-emitting element ink 200 to the first ink storage unit 260, and may distribute the light-emitting elements 30 in the light-emitting element ink 220. The second ink storage unit 210 may supply light-emitting element ink 200 having a uniform (e.g., substantially uniform) degree of dispersion to the first ink storage unit 260 by distributing the light-emitting elements 30 included in the light-emitting element ink 200, provided from an ink injection unit 300 through the third connecting pipe IL3 or provided from the printhead unit 100 through the second connecting pipe IL2, not to sink. The second ink storage unit 210 may function as a buffer storage that stores some of the light-emitting element ink 200 circulated in the ink circulation system.

The second ink storage unit 210 may include a stirrer ST. The stirrer ST may disperse the light-emitting elements 30 in the light-emitting element ink 200. As the stirrer ST rotates, the light-emitting element ink 200 provided to the second ink storage unit 210 may remain dispersed without sinking. In one or more embodiments, the stirrer ST of the second ink storage unit 210 can prevent or reduce settling of the light-emitting elements 30 at the bottom of the second ink storage unit 210 and can thus prevent or reduce any (or substantially any) discrepancy in the number of light-emitting elements 30 included in each unit droplet of the light-emitting element ink 200 ejected through the inkjet head 120.

The pressure pump 250 may be between the printhead unit 100 and the second ink storage unit 210. Light-emitting element ink 200 that remains yet to be ejected from the printhead unit 100 may be provided to the second ink storage unit 210 via the pressure pump 250. The pressure pump 250 may be a pump that delivers power to a fluid so that the light-emitting element ink 200 can be circulated in the ink circulation system.

The injection area IA may be an area that receives the light-emitting element ink 200 from ink bottles BO, which are provided in the inkjet printing device 1000, and provides the light-emitting element ink 200 to the circulation area CA. The injection area IA may include the ink injection unit 300. The ink injection unit 300 may transform high-viscosity light-emitting element ink 200 stored in the ink bottles BO into low-viscosity light-emitting element ink 200 and may provide the low-viscosity light-emitting element ink 200 to the ink circulation unit 270. For example, when the ink bottles BO are provided in the inkjet printing device 1000, the ink injection unit 300 may provide high-viscosity light-emitting element ink 200, for example, solid-state light-emitting element ink 200 or high-viscosity liquid or colloidal light-emitting element ink 200, to the ink circulation unit 270 in the form of low-viscosity liquid or colloidal light-emitting element ink 200. The ink injection unit 300 may deliver the light-emitting element ink 200 provided from an ink preparation unit 400 through a fifth connecting pipe IL5, to the ink circulation unit 270, for example, to the second ink storage unit 210, through the third connecting pipe IL3.

The preparation area PA may be an area in which one or more ink bottles BO are stored before or during a printing process. The preparation area PA may be an area in which the ink bottles BO are stored under set or predetermined conditions so that the sinking of the light-emitting elements 30 can be prevented or reduced to improve the reliability of a printing process.

The preparation area PA may include the ink preparation unit 400. The ink preparation unit 400 may provide the ink bottles BO, in which light-emitting element 200 prepared in advance is stored, to the printing device 1000 or may store the ink bottles BO. The ink preparation unit 400 may provide the light-emitting element ink 200 stored in the ink bottles BO, to the ink injection unit 300 through the fifth connecting pipe IL5.

The manufacture of the display device 10, which involves spraying the light-emitting element ink 200 via the inkjet printing device 1000 will hereinafter be described.

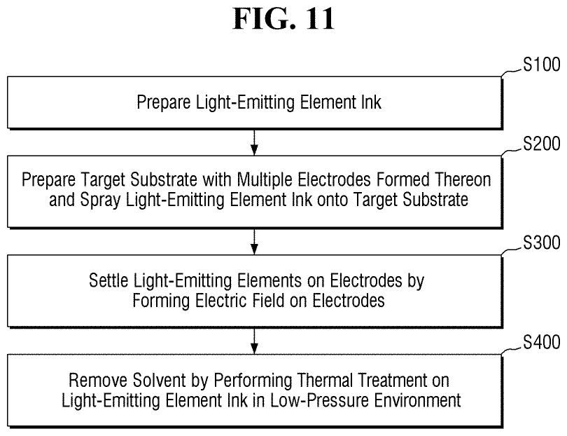

FIG. 11 is a flowchart illustrating a method of manufacturing a display device according to an embodiment of the present disclosure.

Referring to FIG. 11, the method may include: preparing light-emitting element ink 200, which includes light-emitting elements 30, a dispersant 230, and a solvent 220, and a target substrate SUB, on which a plurality of electrodes (21 and 22) are formed (S100); spraying the light-emitting element ink 200 onto the target substrate SUB (S200); and settling the light-emitting elements 30 on the electrodes (21 and 22) by forming an electric field on the electrodes (21 and 22) (S300).

The dispersibility of the light-emitting elements 30 can be improved by using an aqueous dispersant and a solvent having a hydrogen bonding parameter of 7 to 15 or using an organic dispersant and a solvent having a hydrogen bonding parameter of 5 to 7. The method of FIG. 11 will hereinafter be described in further detail.

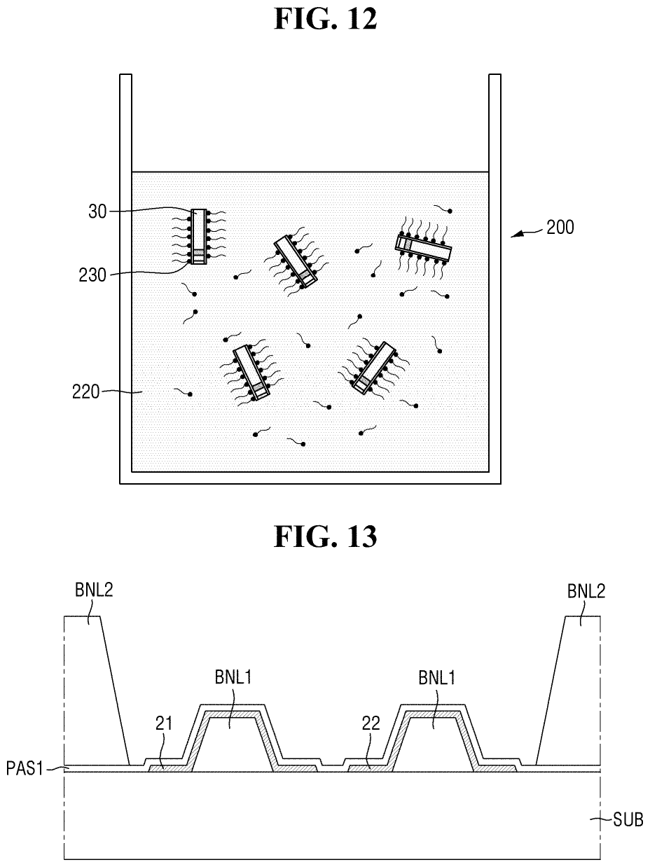

FIGS. 12 through 19 are cross-sectional views illustrating the method of FIG. 11.

Referring to FIGS. 12 and 13, light-emitting element ink 200, which includes light-emitting elements 30, a dispersant 230, and a solvent 220, and a target substrate SUB, on which first and second electrodes 21 and 22, a first insulating layer PAS1, and first banks BNL1 are included, are prepared. FIGS. 9 and 10 illustrate that a pair of electrodes (21 and 22) are provided on the target substrate SUB, but more than one pair of electrodes (21 and 22) may be provided on the target substrate SUB. The target substrate SUB may include the first substrate 11 of the display device 10 and a plurality of circuit elements, which are on the first substrate 11. For convenience, duplicative descriptions and illustrations of the first substrate 11 and the circuit elements will not be repeated here.

The light-emitting element ink 200 may include the solvent 220 and the light-emitting elements 30 and the dispersant 230, which are dispersed in the solvent 220. The light-emitting element ink 200 may include an aqueous dispersant 230 and a solvent 220 having a hydrogen bonding parameter, of Hansen's solubility parameters, of 7 to 15 or may include an organic dispersant 230 and a solvent 220 having a hydrogen bonding parameter, of Hansen's solubility parameters, of 5 to 7. The preparation of the light-emitting element ink 200 may be performed by a dispersion process that mixes the light-emitting elements 30, the dispersant 230, and the solvent 220.

The dispersion process mixes the light-emitting elements 30 and the dispersant 230 in the solvent 220 for five or more minutes. The light-emitting elements 30 may be included in an amount of 0.01% to 10% by weight based on 100% by weight of the entire light-emitting element ink 200, and the dispersant 230 may be included in an amount of 10% to 100% by weight based on 100% by weight of all the light-emitting elements 30. The dispersion process may be performed by sonication, stirring, and/or milling.

The light-emitting element ink 200 obtained by the dispersion process may be stored at room temperature (of about 23° C.). As the light-emitting element ink 200 includes an aqueous dispersant 230 and a solvent 220 having a hydrogen bonding parameter, of Hansen's solubility parameters, of 7 to 15 or includes an organic dispersant 230 and a solvent 220 having a hydrogen bonding parameter, of Hansen's solubility parameters, of 5 to 7, the dispersibility of the light-emitting elements 30 can be improved, and the agglomeration of the light-emitting elements 30 can be prevented or reduced so that the light-emitting elements 30 can remain dispersed without (or substantially without) sinking. The light-emitting element ink 200 may be sufficiently redispersed for five or more minutes via rolling such as, for example, vortexing and/or stirring, before use.

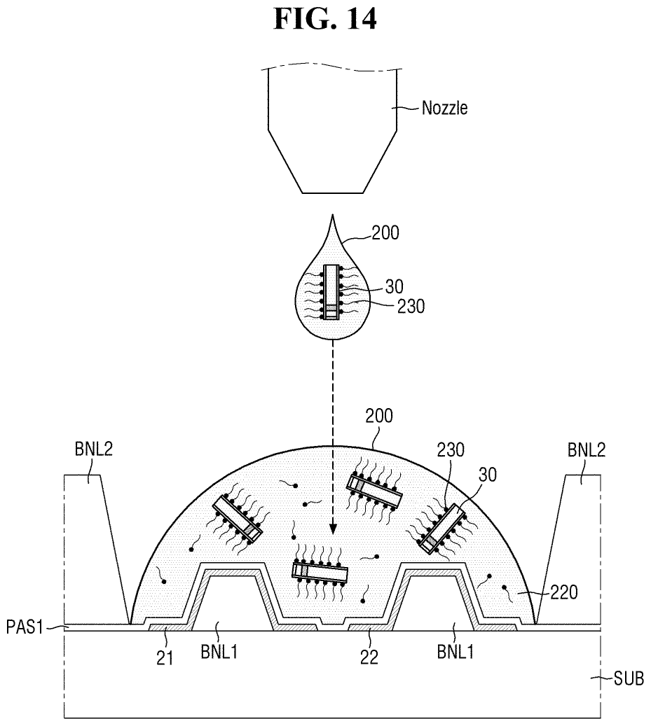

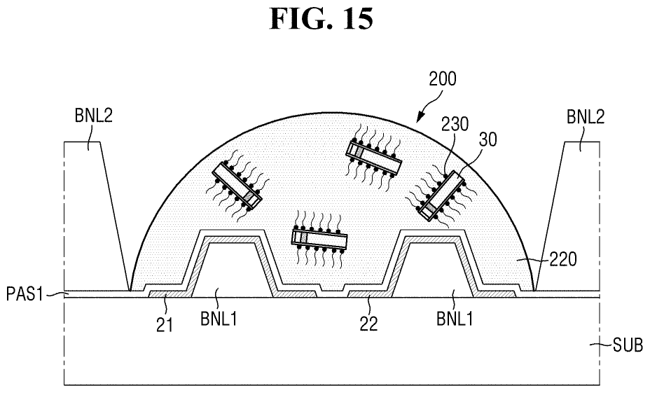

Thereafter, referring to FIGS. 14 and 15, the light-emitting element ink 200 is sprayed on the first insulating layer PAS1, which covers the first and second electrodes 21 and 22 on the target substrate SUB. The light-emitting element ink 200 may be sprayed onto the first insulating layer PAS1 via printing by an inkjet printing device. The light-emitting element ink 200 may be sprayed through the nozzles of an inkjet head of the inkjet printing device. The light-emitting element ink 200 may be ejected onto the target substrate SUB through nozzles provided in the inkjet head. The light-emitting element ink 200 ejected from the nozzles may be settled on the target substrate SUB, for example, on the first insulating layer PAS1 where the first and second electrodes 21 and 22 are formed. The light-emitting elements 30 may extend in one direction and may be dispersed in the light-emitting element ink 200 in random alignment directions.

Once the light-emitting element ink 200 is sprayed onto the first insulating layer PAS1, the light-emitting element ink 200 may evenly spread over a second bank BNL2. As a result, the light-emitting elements 30 dispersed in the light-emitting element ink 200 can be evenly distributed between parts of the second bank BNL2.

Thereafter, the light-emitting elements 30 are settled on the first and second electrodes 21 and 22 (S300) by forming an electric field in the light-emitting element ink 200, and the solvent 220 is removed (S400).

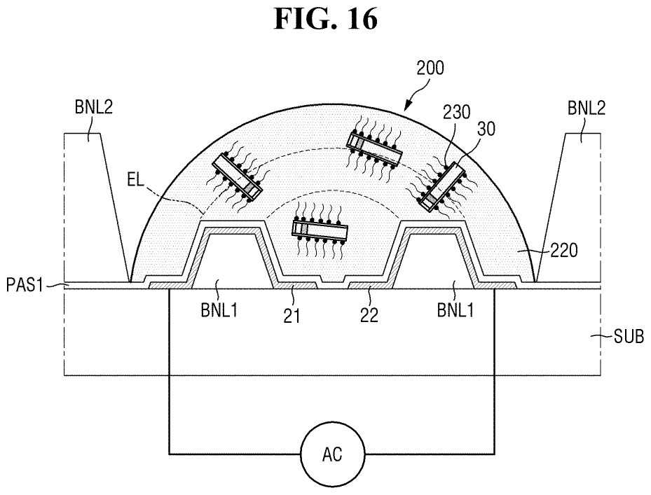

Referring to FIG. 16, once the light-emitting element ink 200 including the light-emitting elements 30 is sprayed onto the target substrate SUB, an electric field EL is formed on the target substrate SUB by applying alignment signals to the first and second electrodes 21 and 22. The light-emitting elements 30 dispersed in the solvent 220 may receive a dielectrophoretic force from the electric field EL, and as the alignment direction and the location of the light-emitting elements 30 change, the light-emitting elements 30 may be aligned on the first and second electrodes 21 and 22.

If the electric field EL is formed on the target substrate SUB, the light-emitting elements 30 may receive a dielectrophoretic force. If the electric field EL is formed in parallel (e.g., substantially in parallel) to the top surface of the target substrate SUB, the light-emitting elements 30 may be aligned on the first and second electrodes 21 and 22 to be in parallel (e.g., substantially in parallel) to the target substrate SUB. The light-emitting elements 30 may move from their initial locations toward the first and second electrodes 21 and 22 due to the dielectrophoretic force. While the locations and the alignment directions of the light-emitting elements 30 are being changed by the electric field EL, both ends of each of the light-emitting elements 30 may be arranged on the first and second electrodes 21 and 22. Each of the light-emitting elements 30 may include semiconductor layers doped with dopants of different conductivity types or kinds and may have a dipole moment. Thus, when placed on the electric field EL, the light-emitting elements 30 may receive a dielectrophoretic force and may thus have both end portions thereof on the first and second electrodes 21 and 22.

The degree of alignment of the light-emitting elements 30 may refer to any deviations in the alignment directions and the locations of the light-emitting elements 30 aligned on the target substrate SUB. For example, if there are large deviations in the alignment directions and the locations of the light-emitting elements 30, the degree of alignment of the light-emitting elements 30 may be understood as being low. On the contrary, if there are only small deviations in the alignment directions and the locations of the light-emitting elements 30, the degree of alignment of the light-emitting elements 30 may be understood as being high or improved.

Once the light-emitting elements 30 are arranged on the first and second electrodes 21 and 22, the removal of the solvent 220 may be performed by applying heat to the light-emitting element ink 200.

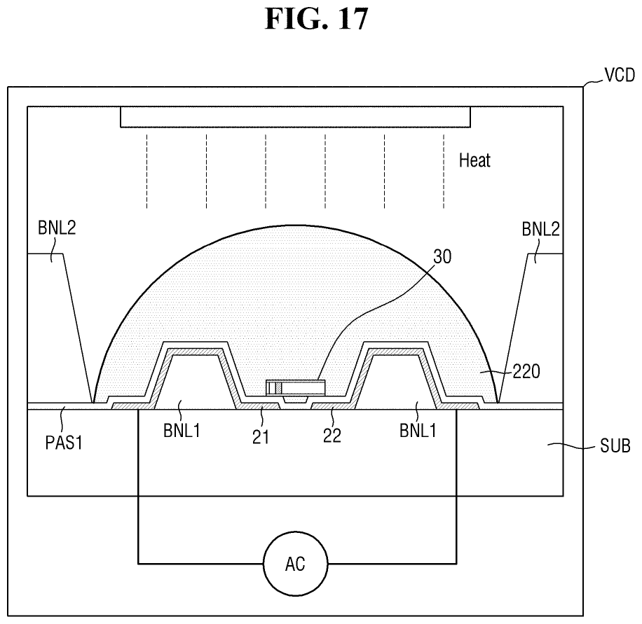

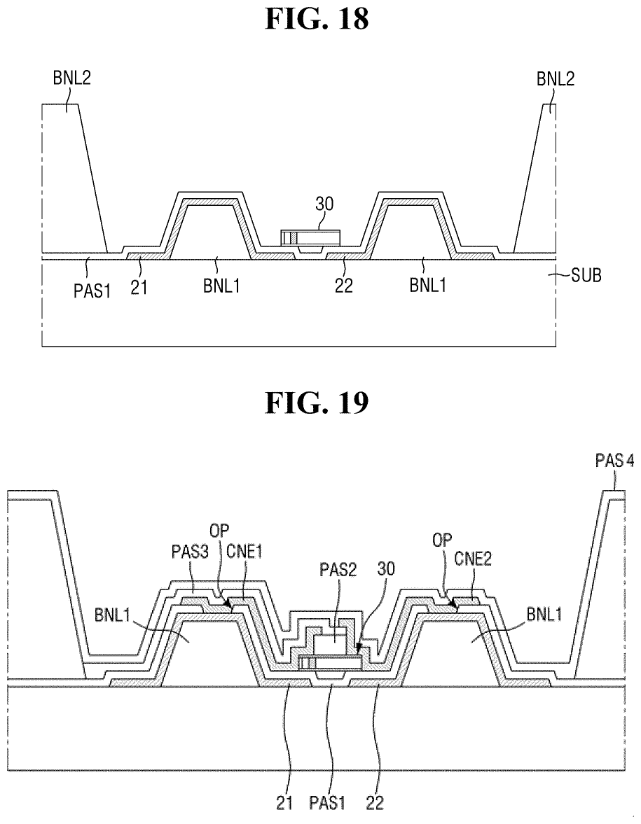

Referring to FIGS. 17 and 18, the removal of the solvent 220 and the dispersant 230 may be performed in a chamber VCD capable of controlling the internal pressure thereof. The chamber VCD may control the internal pressure thereof, and the solvent 220 and the dispersant 230 may be removed by applying heat to the target substrate SUB with the internal pressure of the chamber VCD controlled.

According to the method of FIG. 8, the solvent 220 and the dispersant 230 can be completely removed via thermal treatment in a low-pressure environment. The removal of the solvent 220 and the dispersant 230 may be performed at a pressure of 10⁻⁴ Torr to 1 Torr and at a temperature of 100° C. to 400° C. When thermal treatment is performed within the aforementioned pressure range, the boiling point of the solvent 220 may decrease, and as a result, the removal of the solvent 220 can be facilitated. Thermal treatment may be performed in the chamber VCD for 1 minute to 30 minutes, but the present disclosure is not limited thereto.

Thereafter, referring to FIG. 19, a plurality of insulating layers (PAS1, PAS2, PAS3, and PAS4) and contact electrodes (CNE1 and CNE2) may be formed on the light-emitting elements 30 and the electrodes (21 and 22). In this manner, a display device 10 including the light-emitting elements 30 can be obtained.

The display device 10 may be fabricated using the light-emitting element ink 200, which includes the solvent 220 and the dispersant 230. As the dispersant 230 is formed of a copolymer compound with heads and tails, the heads are bonded to the light-emitting elements 30, and the tails form a chain structure, buoyancy and steric hindrance can be generated in the solvent 220, and as a result, the dispersibility of the light-emitting elements 30 can be increased. Also, as the light-emitting element ink 200 includes a solvent having different hydrogen bonding parameters depending on the type or kind of the dispersant 230, for example, depending on whether the dispersant 230 is an aqueous dispersant or an organic dispersant, the dispersibility of the light-emitting elements 30 can be further increased. Accordingly, even if the light-emitting element ink 200 including the light-emitting elements 30 drops onto each subpixel, the agglomeration of the light-emitting elements 30 can be reduced, the probability of misalignment can be reduced, and the luminance of each subpixel can become uniform (e.g., substantially uniform). Therefore, a uniform (e.g., substantially uniform) number of light-emitting elements 30 can be arranged per unit area of the display device 10 with a high degree of alignment, and the product reliability of the display device 10 can be improved.

Embodiments of the present disclosure will hereinafter be described in further detail with reference to the preparation examples and the experimental examples that follow.

### Preparation Example 1: Preparation of Light-Emitting Element Ink

Ink #1 was prepared by mixing GaN light-emitting elements and a stearic acid dispersant (molecular weight: 284 Mw (Daltons)) in an amount of 0.05% by weight of a tripropylene glycol n-butyl ether (TGBE) solvent. Ink #2 was prepared in substantially the same manner as Ink #1, except for using a dispersant (molecular weight: 15,000 mW (Daltons)) including phosphonic acid and amine as heads and polyacrylate as tails.

### Experimental Example 1: Evaluation of Redispersion of Light-Emitting Element Ink in Accordance with Dispersant

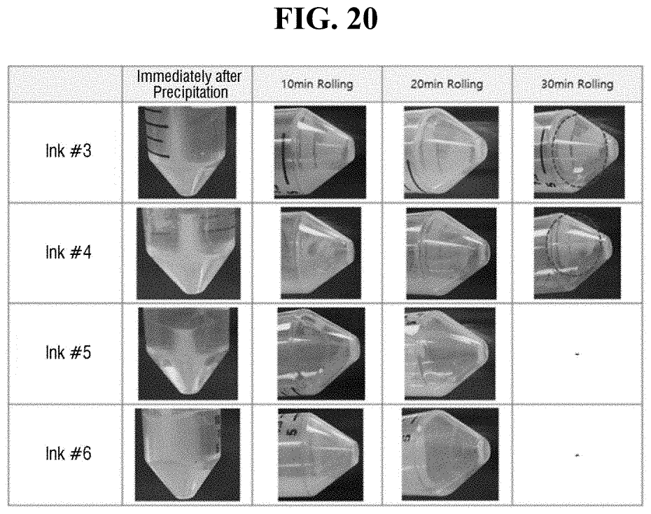

Ink #1 and ink #2 were redispersed by 3-, 5-, and 10-minute rolling immediately after precipitation, and the presence of any residual deposits in ink #1 and ink #2 was measured based on images captured from ink #1 and ink #2. The results of the measurement are as shown in FIG. 20.

Referring to FIG. 20, the presence of residual deposits was confirmed from ink #1 even after 5-minute rolling, but no residual deposits were found in ink #2 from 5-minute rolling. Given this, it is identified that the use of the dispersant according to an embodiment of the present disclosure can improve dispersion stability due to an excellent redistribution property.

### Preparation Example 2: Preparation of Light-Emitting Element Ink

Ink #3 was prepared in substantially the same manner as ink #1, except for using only a DGPE solvent. Ink #4 was prepared in substantially the same manner as Ink #3, except for using a dispersant (molecular weight: 3,000 mW (Daltons)) including phosphonic acid as heads and fatty acid as tails. Ink #5 was prepared in substantially the same manner as Ink #3, except for using a dispersant (molecular weight: 15,000 mW (Daltons)) including phosphonic acid and amine as heads and polyacrylate as tails. Ink #6 was prepared in substantially the same manner as Ink #3, except for using a dispersant (molecular weight: 80,000 mW (Daltons)) including amine as heads and polyurethane as tails.

### Experimental Example 2: Evaluation of Redistribution of Light-Emitting Element Ink in Accordance with Molecular Weight of Dispersant

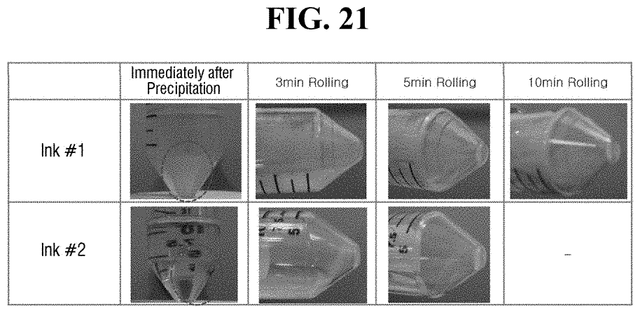

Ink #3, ink #4, ink #5, and ink #6 were redispersed by 10-, 20-, and 30-minute rolling immediately after precipitation, and the presence of any residual deposits in ink #3, ink #4, ink #5, and ink #6 was measured based on images captured from ink #3, ink #4, ink #5, and ink #6. The results of the measurement are as shown in FIG. 21.

### Experimental Example 3: Evaluation of Sinking Speed of Light-Emitting Elements in Accordance with Molecular Weight of Dispersant

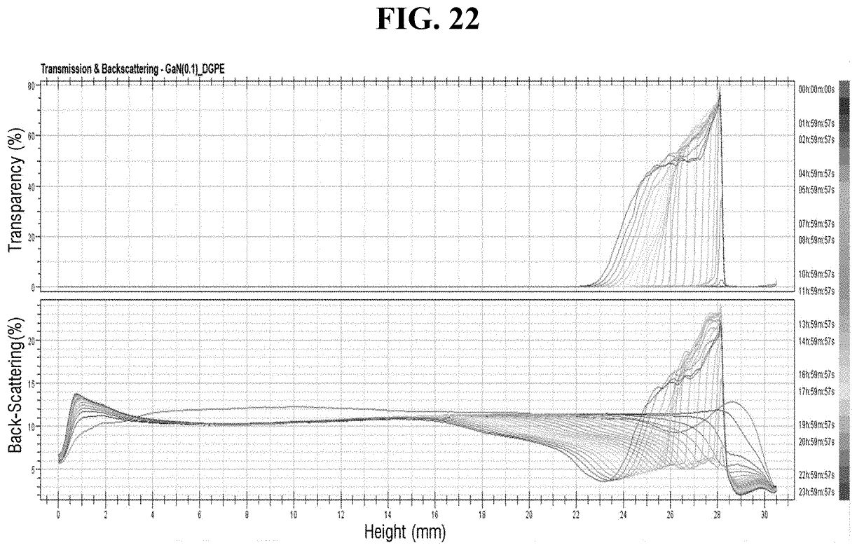

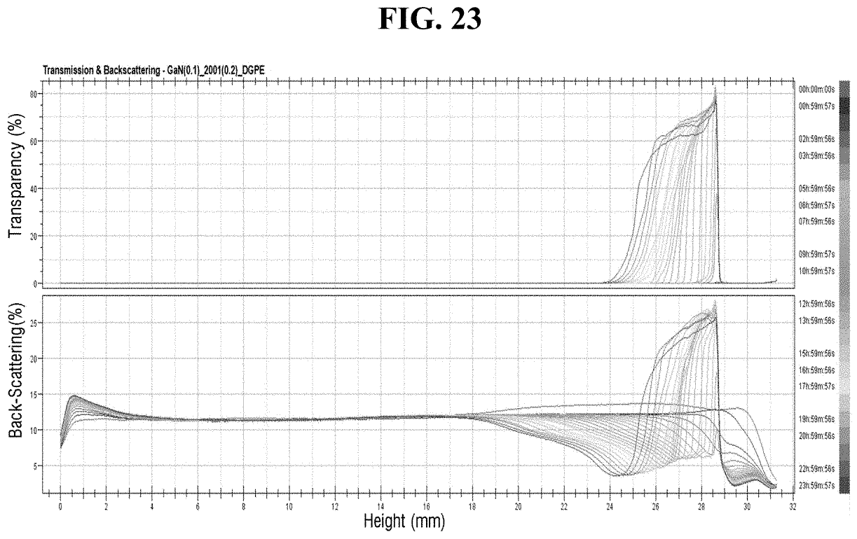

Ink #3 and ink #5 were mixed and filled into bottles, and then, the transparency and back-scattering of ink #3 and ink #5 were measured over time. The results of the measurement are as shown in FIGS. 22 and 23, respectively. That is, FIG. 22 is a graph showing the change of the transparency and the back-scattering of ink #3 over time according to Experimental Example 3, and FIG. 23 is a graph showing the change of the transparency and the back-scattering of ink #5 over time according to Experimental Example 3. Referring to FIGS. 22 and 23, the horizontal axes represent the height of the bottles, and the colors of curves represent time.

Referring to FIG. 21, residual deposits were found from ink #3 and ink #4 after 30-minute rolling, but no residual deposits were found from ink #5 and ink #6 even after 20-minute rolling. No residual deposits were found from ink #3 only after one-hour rolling.

Referring to FIGS. 22 and 23, the transparency of ink #3 and ink #5 increases over time at the tops of the bottles, but are almost zero in the rest of the bottles. The back-scattering of ink #3 and ink #5 gradually decreases over time at the tops of the bottles. Ink #3 has a back-scattering value of 10% to 14%, and ink #5 has a back-scattering value of 11% to 15%. The sinking speed of light-emitting elements is 0.16 mm/hour in ink #5 and 0.22 mm/hour in ink #3. Ink #5 exhibits an about 30% slower sinking speed than ink #3.

Experimental Examples 2 and 3 show that a dispersant having a range of molecular weights according to an embodiment of the present disclosure exhibit an excellent redistribution property and can thus improve dispersion stability, and that a dispersant having the range of molecular weights according to an embodiment of the present disclosure can further lower the sinking speed of light-emitting elements and can thus improve the dispersibility of light-emitting elements.

### Preparation Example 3: Preparation of Light-Emitting Element Ink

Ink #7 was prepared by mixing GaN light-emitting elements in an amount of 0.2% by weight of a mixed solvent (85:15) of DGPE and GL. Ink #8 was prepared in substantially the same manner as Ink #7, except for using a dispersant (molecular weight: 15,000 mW (Daltons)) including phosphonic acid and amine as heads and polyacrylate as tails.

### Experimental Example 4: Evaluation of Dispersion Stability of Light-Emitting Element Ink Depending on Presence of Dispersant

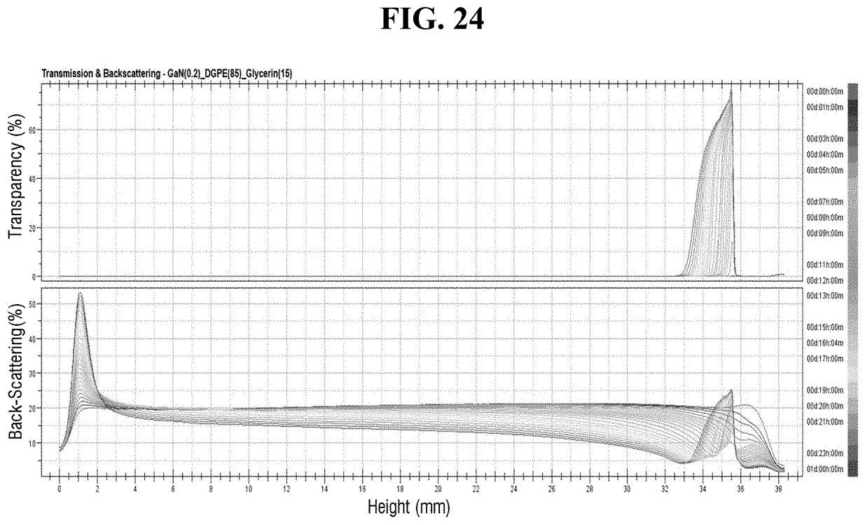

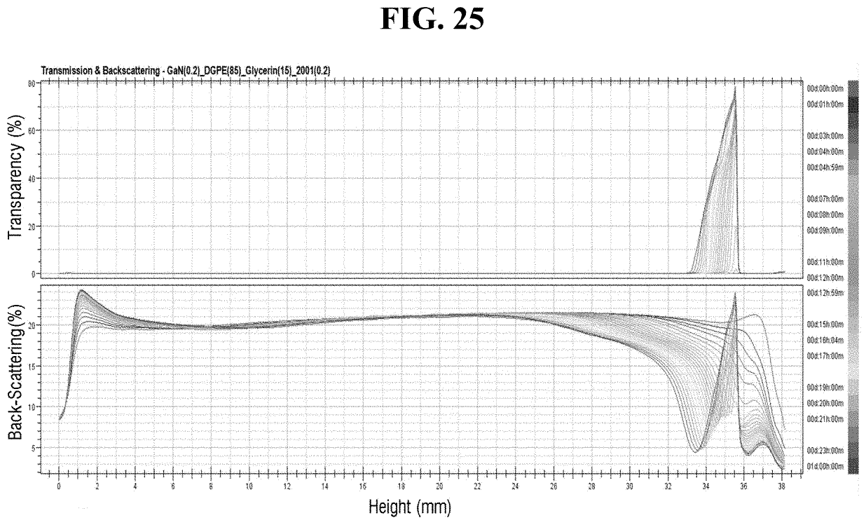

Ink #7 and ink #8 were mixed and filled into bottles, and then, the transparency and back-scattering of ink #7 and ink #8 were measured over time. The results of the measurement are as shown in FIGS. 24 and 25, respectively. That is, FIG. 24 is a graph showing the change of the transparency and the back-scattering of ink #7 over time according to Experimental Example 4, and FIG. 25 is a graph showing the change of the transparency and the back-scattering of ink #8 over time according to Experimental Example 4.

Referring to FIGS. 24 and 25, the transparency of ink #7 and ink #8 increases over time at the tops of the bottles, but are almost zero in the rest of the bottles. The back-scattering of ink #7 and ink #8 gradually decreases over time at the tops of the bottles. On the contrary, ink #6 generally shows a back-scattering value of 10% to 20% and has a back-scattering value of 50% or greater at the bottom of the bottle. Ink #5 generally shows a uniform (e.g., substantially uniform) back-scattering value of 20% or greater from the bottom to the top of the bottle.

Experimental Example 4 shows that light-emitting element ink including a dispersant according to an embodiment of the present disclosure can generally distribute light-emitting elements without (or substantially without) sinking to the bottom, whereas in light-emitting element ink including no dispersant, light-emitting elements gradually sink to the bottom over time. Thus, the light-emitting element ink according to an embodiment of the present disclosure can improve the dispersibility and the dispersion stability of light-emitting elements.

In concluding the detailed description, those skilled in the art will appreciate that many variations and modifications can be made to the preferred embodiments without substantially departing from the principles of the present disclosure. Therefore, the disclosed example embodiments of the disclosure are used in a generic and descriptive sense only and not for purposes of limitation.

What is claimed is:

1. A light-emitting element ink comprising:
a solvent;
a dispersant mixed with the solvent; and
a plurality of light-emitting elements dispersed in the solvent, each of the light-emitting elements comprising a plurality of semiconductor layers and an insulating film surrounding parts of outer surfaces of the semiconductor layers,
wherein:
the dispersant comprises an aqueous dispersant or an organic dispersant,
if the dispersant is the aqueous dispersant, the solvent has a hydrogen bonding parameter, of Hansen's solubility parameters, of less than 7, and
if the dispersant is the organic dispersant, the solvent has a hydrogen bonding parameter, of Hansen's solubility parameters, of 7 or greater.

2. The light-emitting element ink of claim 1, wherein:
the solvent comprises a copolymer compound comprising heads, which are bonded to the light-emitting elements, and tails, which are coupled to the heads, and
the copolymer compound comprises a polymer self-assembly monolayer (P-SAM).

3. The light-emitting element ink of claim 2, wherein the heads comprise at least one selected from among phosphonic acid, carboxylic acid, trimethoxysilane, and amine.

4. The light-emitting element ink of claim 3, wherein the tails comprise at least one selected from among polyalkylene oxide, polyurethane, polyacrylate, alkyl, amine, fatty acid, and polyester.

5. The light-emitting element ink of claim 1, wherein the dispersant has a molecular weight of 1,000 to 100,000 Daltons.

6. The light-emitting element ink of claim 1, wherein if the dispersant is the aqueous dispersant, the solvent has a hydrogen bonding parameter, of Hansen's solubility parameters, of 7 to 15.

7. The light-emitting element ink of claim 1, wherein if the dispersant is the organic dispersant, the solvent has a hydrogen bonding parameter, of Hansen's solubility parameters, of 5 or more and less than 7.

8. The light-emitting element ink of claim 1, wherein the light-emitting elements are included in an amount of 0.01% to 10% by weight based on 100% by weight of the light-emitting element ink.

9. The light-emitting element ink of claim 8, wherein the dispersant is included in an amount of 10% to 100% by weight based on 100% by weight of the light-emitting elements.

10. The light-emitting element ink of claim 1, wherein:
the semiconductor layers comprise a first semiconductor layer and a second semiconductor layer and a light-emitting layer, which is between the first semiconductor layer and the second semiconductor layer, and
the insulating film surrounds an outer surface of at least the light-emitting layer.

11. The light-emitting element ink of claim 9, wherein the dispersant is chemically bonded to the insulating film.

12. A method of manufacturing a display device, comprising:
preparing light-emitting element ink, which comprises a solvent, a dispersant, and a plurality of light-emitting elements, and a target substrate, on which the first electrode and the second electrode are formed;
spraying the light-emitting element ink onto the target substrate; and
settling the light-emitting elements on the first electrode and the second electrode by forming an electric field on the target substrate,
wherein:
the dispersant comprises an aqueous dispersant or an organic dispersant,
if the dispersant is the aqueous dispersant, the solvent has a hydrogen bonding parameter, of Hansen's solubility parameters, of less than 7, and
if the dispersant is the organic dispersant, the solvent has a hydrogen bonding parameter, of Hansen's solubility parameters, of 7 or greater.

13. The method of claim 12, wherein:
the solvent comprises a copolymer compound comprising heads, which are bonded to the light-emitting elements, and tails, which are coupled to the heads, and
the copolymer compound comprises a polymer self-assembly monolayer (P-SAM).

14. The method of claim 13, wherein the heads comprise at least one selected from among phosphonic acid, carboxylic acid, trimethoxysilane, and amine.

15. The method of claim 14, wherein the tails comprise at least one selected from among polyalkylene oxide, polyurethane, polyacrylate, alkyl, amine, fatty acid, and polyester.

16. The method of claim 12, wherein the dispersant has a molecular weight of 1,000 to 100,000 Daltons.

17. The method of claim 12, wherein if the dispersant is the aqueous dispersant, the solvent has a hydrogen bonding parameter, of Hansen's solubility parameters, of 7 to 15.

18. The method of claim 12, wherein if the dispersant is the organic dispersant, the solvent has a hydrogen bonding parameter, of Hansen's solubility parameters, of 5 or more and less than 7.

19. The method of claim 12, wherein:
the light-emitting elements are included in an amount of 0.01% to 10% by weight based on 100% by weight of the light-emitting element ink, and
the dispersant is included in an amount of 10% to 100% by weight based on 100% by weight of the light-emitting elements.

20. The method of claim 12, further comprising, after the settling the light-emitting elements:
removing the solvent and the dispersant by performing thermal treatment.
